(19) United States
(12) Patent Application Publication
(10) Pub. No.: US 2025/0378893 A1
(43) Pub. Date: Dec. 11, 2025

(54) METHOD OF OPERATING NONVOLATILE MEMORY DEVICE AND NONVOLATILE MEMORY DEVICE

(71) Applicant: Samsung Electronics Co., Ltd., Suwon-si (KR)

(72) Inventors: Hojoon Kim, Suwon-si (KR); Yohan Lee, Suwon-si (KR); Sangsoo Park, Suwon-si (KR); Jaeyun Lee, Suwon-si (KR)

(21) Appl. No.: 19/005,393

(22) Filed: Dec. 30, 2024

(30) Foreign Application Priority Data
Jun. 5, 2024 (KR) 10-2024-0073506

(51) Int. Cl. G11C 16/34; G11C 16/08; G11C 16/16; G11C 16/32

(52) U.S. Cl. CPC G11C 16/3418; G11C 16/08; G11C 16/16; G11C 16/32

(57) ABSTRACT

There is provided a method of operating a nonvolatile memory device that includes a plurality of memory blocks, each of the plurality of memory blocks including a plurality of cell strings where each of the plurality of cell strings includes a string selection transistor, a plurality of memory cells, and a ground selection transistor which are connected in series and arranged in a vertical direction between each of a plurality of bit-lines and a common source line on and/or in a substrate, the method comprising: receiving an erase command and a block address designating a target memory block among the plurality of memory blocks; sensing an operating temperature of the nonvolatile memory device; and adjusting an erase execution time interval of each of word-lines of the target memory block, respectively, based on the sensed operating temperature, wherein the vertical direction is perpendicular to an upper surface of the substrate.

### CROSS-REFERENCE TO RELATED APPLICATION(S)

This US application claims priority under 35 USC § 119 to Korean Patent Application No. 10-2024-0073506, filed on Jun. 5, 2024, in the Korean Intellectual Property Office (KIPO), the disclosure of which is incorporated herein by reference in its entirety.

### BACKGROUND

Example embodiments generally relate to semiconductor memory devices, and more particularly to a method of operating a nonvolatile memory device and a nonvolatile memory device performing the same.

Semiconductor memory devices for storing data may be classified into volatile memory devices and nonvolatile memory devices. Volatile memory devices, such as dynamic random access memory (DRAM) devices, are typically configured to store data by charging or discharging capacitors in memory cells, and lose the stored data when power is off. Nonvolatile memory devices, such as flash memory devices, may maintain stored data even though power is off. Volatile memory devices are widely used as main memories of various apparatuses, while nonvolatile memory devices are widely used for storing program codes and/or data in various electronic devices, such as computers, mobile devices, etc.

Recently, nonvolatile memory devices of three-dimensional structure such as a vertical NAND memory devices have been developed to increase integration degree and memory capacity of the nonvolatile memory devices. Along with increases in the integration degree and memory capacity, a portion of memory cells may be over-erased due to operating temperature in erase operation on the nonvolatile memory device.

### SUMMARY

Some example embodiments may provide method of operating a nonvolatile memory device, capable of preventing memory cells from being over-erased.

Some example embodiments may provide a nonvolatile memory device capable of preventing memory cells from being over-erased.

According to example embodiments, there is provided a method of operating a nonvolatile memory device that includes a plurality of memory blocks, each of the plurality of memory blocks including a plurality of cell strings where each of the plurality of cell strings includes a string selection transistor, a plurality of memory cells, and a ground selection transistor which are connected in series and arranged in a vertical direction between each of a plurality of bit-lines and a common source line on and/or in a substrate, the method comprising: receiving an erase command and a block address designating a target memory block among the plurality of memory blocks; sensing an operating temperature of the nonvolatile memory device; and adjusting an erase execution time interval of each of word-lines of the target memory block, respectively, based on the sensed operating temperature, wherein the vertical direction is perpendicular to an upper surface of the substrate.

According to example embodiments, a nonvolatile memory device includes a memory cell array including a plurality of memory blocks, each of the plurality of memory blocks including a plurality of cell strings where each of the plurality of cell strings includes a string selection transistor, a plurality of memory cells, and a ground selection transistor which are connected in series and arranged in a vertical direction between each of a plurality of bit-lines and a common source line on and/or in a substrate; a digital temperature sensor configured to sense an operating temperature of the nonvolatile memory device; and a control circuit configured to control an erase operation on a target memory block among the plurality of memory blocks by; receiving an erase command and a block address designating the target memory block; and adjusting an erase execution time interval of each of word-lines of the target memory block, respectively, based on the sensed operating temperature, and wherein the vertical direction is perpendicular to an upper surface of the substrate.

According to example embodiments, a nonvolatile memory device includes a memory cell array including a plurality of memory blocks, each of the plurality of memory blocks including a plurality of cell strings where each of the plurality of cell strings includes a string selection transistor, a plurality of memory cells, and a ground selection transistor which are connected in series and arranged in a vertical direction between each of a plurality of bit-lines and a common source line on and/or in a substrate; a digital temperature sensor configured to sense an operating temperature of the nonvolatile memory device; and a control circuit configured to control an erase operation on a target memory block among the plurality of memory blocks by; receiving an erase command and a block address designating the target memory block; and adjusting an erase execution time interval of each of word-lines of the target memory block, respectively, based on the sensed operating temperature, wherein the control circuit is configured to: divide the word-lines of the target memory block into a plurality of word-line groups based on a distance in the vertical direction from the common source line; apply an erase voltage to a channel of the target memory block during an erase execution time period that comprises the erase execution time interval; apply a word-line erase voltage to the word-lines of the target memory block while the erase voltage having a first target voltage is applied; and adjust time point of applying an erase inhibit voltage to word-lines in each of the word-line groups, based on a digital temperature code corresponding to the sensed operating temperature, and wherein the vertical direction is perpendicular to an upper surface of the substrate.

Accordingly, in a nonvolatile memory device and a method of operating a nonvolatile memory device according to example embodiments, the memory cells of the target memory block may be prevented from being over-erased in the cold temperature range by adjusting erase execution time interval differently in the hot temperature condition and in the cold temperature condition.

### BRIEF DESCRIPTION OF THE DRAWINGS

Illustrative, non-limiting example embodiments will be more clearly understood from the following detailed description in conjunction with the accompanying drawings.

FIG. 1 is a flow chart illustrating a method of operating a nonvolatile memory device according to example embodiments.

FIG. 2 is a flow chart illustrating an operation of adjusting the erase execution time interval of each of word-lines of the target memory block individually in FIG. 1 according to example embodiments.

FIG. 3 is a flow chart illustrating an operation of adjusting the erase execution time interval of each of the word-line groups individually based on the sensed temperature in FIG. 2 according to example embodiments.

FIG. 4 is a flow chart illustrating an operation of performing a first erase operation in FIG. 3 according to example embodiments.

FIG. 5 is a flow chart illustrating an operation of performing a second erase operation in FIG. 3 according to example embodiments.

FIG. 6 is a timing diagram illustrating a method of operating a nonvolatile memory device according to example embodiments.

FIG. 7 is a block diagram illustrating a memory system according to example embodiments.

FIG. 8 is a block diagram illustrating an example of the memory controller in the memory system in FIG. 7 according to example embodiments.

FIG. 9 is a block diagram illustrating an example of the nonvolatile memory device in the memory system of FIG. 7 according to example embodiments.

FIG. 10 schematically illustrates a structure of the nonvolatile memory device of FIG. 9 according to example embodiments.

FIG. 11 is a block diagram illustrating an example of the memory cell array in the nonvolatile memory device of FIG. 9 according to example embodiments.

FIG. 12 is a circuit diagram illustrating one of the memory blocks of FIG. 11 according to example embodiments.

FIG. 13 illustrates an example of a structure of a cell string in the memory block of FIG. 12.

FIGS. 14A, 14B, and 14C illustrate examples of one of cell strings in FIG. 13, respectively, according to example embodiments.

FIG. 15 is a block diagram illustrating the control circuit in the nonvolatile memory device of FIG. 9 according to example embodiments.

FIG. 16 is a block diagram illustrating the voltage generator in the nonvolatile memory device of FIG. 9 according to example embodiments.

FIG. 17 is a block diagram illustrating an example of the address decoder in the nonvolatile memory device of FIG. 9 according to example embodiments.

FIG. 18 illustrates an example operation of one of the plurality of switches in the address decoder of FIG. 17 according to example embodiments.

FIG. 19A is a graph showing a threshold voltage distributions of memory cells in FIG. 12.

FIG. 19B illustrates an erase distribution width of a plurality of word-lines.

FIG. 20 is a block diagram illustrating an example of a digital temperature sensor in the nonvolatile memory device of FIG. 9 according to example embodiments.

FIG. 21A illustrates a digital temperature code based on the operating temperature and compensation amount on a portion of the word-line groups based on the operating temperature according to example embodiments.

FIG. 21B illustrates a digital temperature code based on the operating temperature and compensation amount on a portion of the word-line groups based on the operating temperature according to example embodiments.

FIG. 21C illustrates a digital temperature code based on the operating temperature and compensation amount on a portion of the word-line groups based on the operating temperature according to example embodiments.

FIG. 22 is a timing diagram illustrating a method of operating a nonvolatile memory device according to example embodiments.

FIG. 23 illustrates an example of a cell string on which an erase operation is performed according to example embodiments.

FIGS. 24A and 24B are diagrams of examples of word-line groups included in a memory block on which an erase operation is performed, according to example embodiments.

FIG. 25 illustrates an example of a plurality of erase loops performed on at a target memory block according to example embodiments.

FIG. 26 is a block diagram illustrating a storage device according to example embodiments.

### DETAILED DESCRIPTION OF THE EMBODIMENTS

Various example embodiments will be described more fully hereinafter with reference to the accompanying drawings, in which some example embodiments are shown.

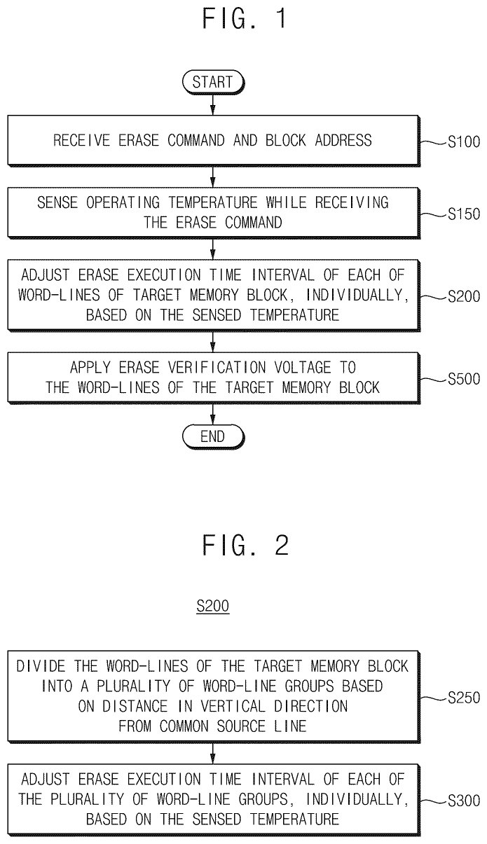

FIG. 1 is a flow chart illustrating a method of operating a nonvolatile memory device according to example embodiments.

FIG. 1 illustrates a method of operating a nonvolatile memory device including at least one memory block which includes a plurality of cell strings, where each cell string includes a string selection transistor, a plurality of memory cells and a ground selection transistor (electrically) connected in series in a vertical direction between a bit-line and a common source line. According to example embodiments, the nonvolatile memory device may include a three-dimensional NAND flash memory device or a vertical NAND flash memory device.

Referring to FIG. 1, the nonvolatile memory device may receive an erase command and a block address designating a target memory block among the plurality of memory blocks from an external memory controller (operation S100). As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

A temperature sensor in the nonvolatile memory device may sense an operating temperature of the nonvolatile memory device while receiving the erase command (operation S150).

A control circuit in the nonvolatile memory device may adjust erase execution time interval of each of word-lines of the target memory block, individually (respectively), based on the sensed temperature (operation S200).

The control circuit may verify erased states of memory cells coupled to word-lines of the target memory block by applying an erase verification voltage to the word-lines of the target memory block (operation S500).

Erase distribution of erased state of the memory cells of the target memory block may be changed due to change of the operating temperature of the nonvolatile memory device. When an erase execution time interval in hot temperature range is the same as an erase execution time interval in cold temperature range, the memory cells of the target memory block may be over-erased in the cold temperature range and thus, the erase distribution of erased state of the memory cells of the target memory block may be degraded. However, in a method of operating a nonvolatile memory device according to example embodiments, erase execution time interval of each of word-lines of the target memory block is adjusted, individually (respectively), based on the sensed temperature, and thus, erase distribution width of memory cells coupled to the word-lines of the target memory block, generated by a change of the operation temperature may be reduced.

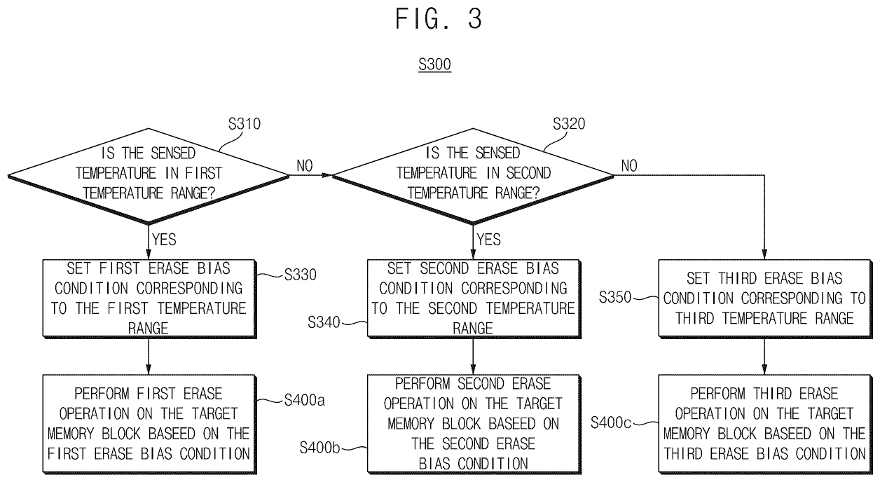

FIG. 2 is a flow chart illustrating an operation of adjusting the erase execution time interval of each of word-lines of the target memory block individually (respectively) in FIG. 1 according to example embodiments.

Referring to FIG. 2, for adjusting the erase execution time interval of each of word-lines of the target memory block individually (respectively) (operation S200), the word-lines of the target memory block may be divided into a plurality of word-line groups based on a distance in the vertical direction from the common source line (operation S250), and erase execution time interval of each of the word-line groups may be adjusted individually (respectively) based on the sensed temperature (operation S300).

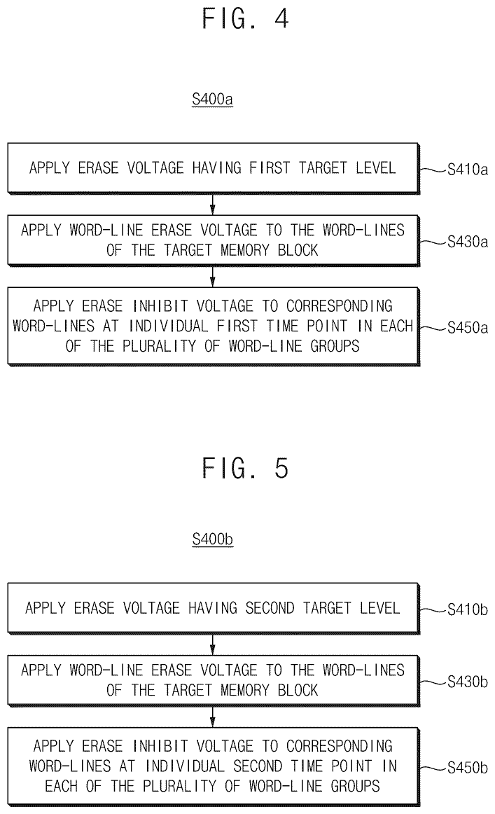

FIG. 3 is a flow chart illustrating an operation of adjusting the erase execution time interval of each of the word-line groups individually (respectively) based on the sensed temperature in FIG. 2 according to example embodiments.

Referring to FIG. 3, for adjusting the erase execution time interval of each of the word-line groups individually (respectively) based on the sensed temperature (operation S300), it is determining that the sensed temperature is in which one of a plurality of temperature ranges. (operations S310 and S320).

It is determined whether the sensed temperature is in a first temperature range greater than a first reference temperature (operation S310). The first temperature range may be a hot temperature range. When the sensed temperature is in the first temperature range (Yes in operation S310), e.g., in response to the sensed temperature is in the first temperature range, a first erase bias condition corresponding to the first temperature range may be set (operation S330) and a first erase operation may be performed on the target memory block based on the first erase bias condition (operation S400a). Herein, when a temperature A is referred to as greater than a temperature B, the temperature A is hotter than the temperature B. Also, when a temperature A is referred to as smaller than a temperature B, the temperature A is colder than the temperature B.

When the sensed temperature is not in the first temperature range (No in operation S310), it is determined whether the sensed temperature is in a second temperature range smaller than a second reference temperature (operation S320). The second temperature range may be a cold temperature range. When the sensed temperature is in the second temperature range (Yes in operation S320), e.g., in response to the sensed temperature is in the second temperature range, a second erase bias condition corresponding to the second temperature range may be set (operation S340) and a second erase operation may be performed on the target memory block based on the second erase bias condition (operation S400b).

When the sensed temperature is not in the second temperature range (No in operation S320), it is determined that the sensed temperature is in a third temperature range between the first temperature range and the second temperature range and a third erase bias condition corresponding to the third temperature range may be set (operation S350) and a third erase operation may be performed on the target memory block based on the third erase bias condition (operation S400c).

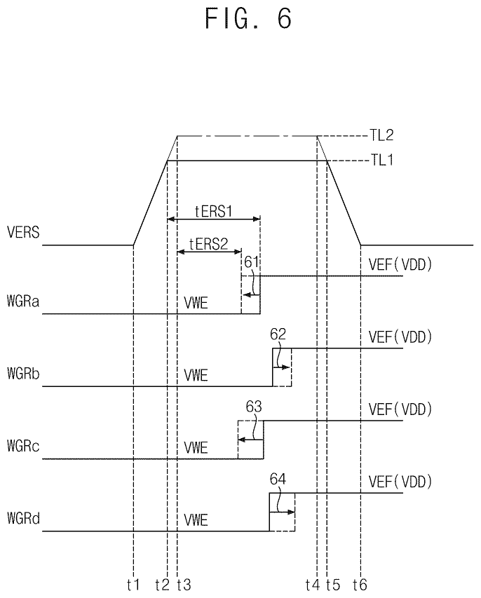

FIG. 4 is a flow chart illustrating an operation of performing a first erase operation in FIG. 3 according to example embodiments.

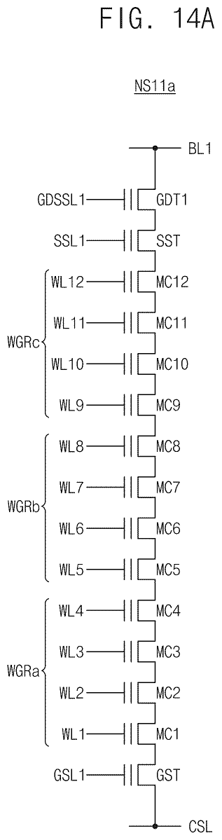

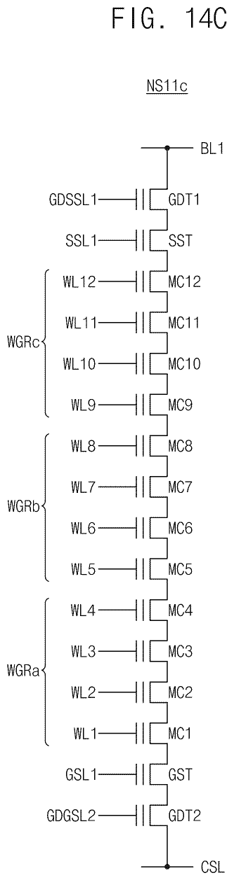

Referring to FIG. 4, for performing a first erase operation on the target memory block based on the first erase bias condition, an erase voltage having a first target level may be applied to a substrate in which the plurality of cell strings are provided or a channel of the target memory block during an erase execution (time) period (operation S410a). When each of the plurality of cell strings is implemented with each of a plurality of cell strings NS11, NS21, NS31, NS12, NS22, NS32, NS13, NS23 and NC33 in FIG. 12, the erase voltage may be applied to the substrate and when each of the plurality of cell strings is implemented with each of a plurality of cell strings NS11a, NS11b and NS11c in FIGS. 14A, 14B and 14C, the erase voltage may be applied to a channel of the target memory block (e.g., a channel of each of the cell strings). Herein, the term “level” may refer to “voltage level” or “voltage”. For example, a target level may refer to a target voltage.

A word-line erase voltage may be applied to the word-lines of the target memory block while the erase voltage having the first target level is applied (operation S430a). The word-line erase voltage may have a voltage level of a ground voltage.

An erase inhibit voltage may be applied to word-lines in each of the word-line groups at an individual (a corresponding) first time point in the erase execution (time) period (operation S450a). The erase inhibit voltage may have a voltage level that is greater than the word-line erase voltage and smaller than or similar with (e.g., equal to) the erase voltage. The erase inhibit voltage may be also referred to as an erase forbidden voltage.

The erase execution time interval of each of the word-line groups may correspond to a time interval from a time point at which the erase voltage has the first target level to a time point at which the erase inhibit voltage is applied. The erase execution time interval may be referred to as an effective erase execution time interval. Memory cells coupled to word-lines of each of the word-line groups may be erased during the erase execution time interval.

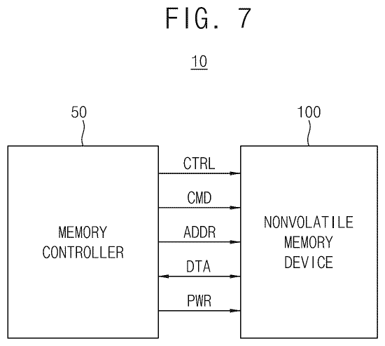

FIG. 5 is a flow chart illustrating an operation of performing a second erase operation in FIG. 3 according to example embodiments.

Referring to FIG. 5, for performing a second erase operation on the target memory block based on the second erase bias condition, an erase voltage having a second target level may be applied to a substrate in which the plurality of cell strings are provided or a channel of the target memory block during an erase execution (time) period (operation S410b). The second target level may be greater than the first target level associated with the first erase operation.

A word-line erase voltage may be applied to the word-lines of the target memory block while the erase voltage having the second target level is applied (operation S430b). The word-line erase voltage may have a voltage level of a ground voltage.

An erase inhibit voltage may be applied to word-lines in each of the word-line groups at an individual (a corresponding) second time point in the erase execution (time) period (operation S450b). The erase inhibit voltage may have a voltage level that is greater than the word-line erase voltage and smaller than or similar with (e.g., equal to) the erase voltage. The second time point may be different from the first time point associated with the first erase operation.

The erase execution time interval of each of the word-line groups may correspond to a time interval from a time point at which the erase voltage has the second target level to a time point at which the erase inhibit voltage is applied. Memory cells coupled to word-lines of each of the word-line groups may be erased during the erase execution time interval.

In example embodiments, the second time point may be earlier than the first time point in a first word-line group among the plurality of word-line groups, and the second time point may be later than the first time point in a second word-line group different from the first word-line group among the plurality of word-line groups.

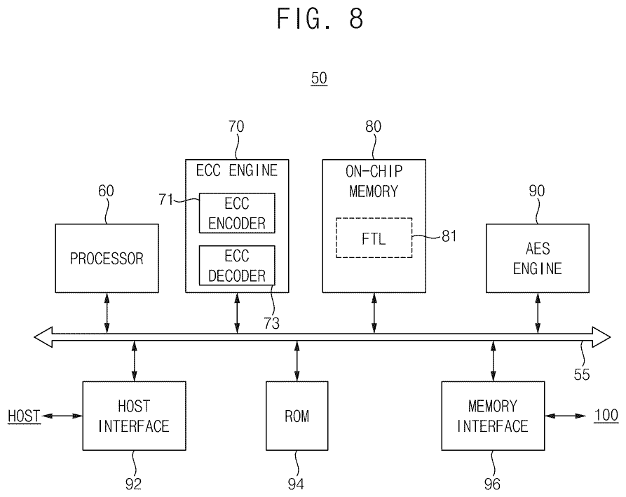

FIG. 6 is a timing diagram illustrating a method of operating a nonvolatile memory device according to example embodiments.

FIG. 6 illustrates an erase execution (time) period of one of a plurality of erase loops. In FIG. 6, bolded lines represent an erase voltage, a word-line erase voltage, and an erase inhibit voltage applied to the word-line groups when the sensed temperature is in the first temperature range (e.g., a hot temperature range) and dotted lines represent an erase voltage, a word-line erase voltage, and an erase inhibit voltage applied to the word-line groups when the sensed temperature is in the second temperature range (e.g., a cold temperature range).

In FIG. 6, assuming that word-lines of the target memory block are divided into a plurality of word-line groups WGRa, WGRb, WGRc and WGRd.

Referring to FIG. 6, when the sensed temperature is in the first temperature range, an erase voltage VERS, which is applied to a channel of the target memory block, may start to ramp at a time point t1, arrive at a target level TL1 at a time point t2, start to drop at a time point t5, and arrive at a ground voltage level at a time point at t6. A word-line erase voltage VWE greater than the ground voltage may be applied to word-lines of each of the word-line groups WGRa, WGRb, WGRc and WGRd until an individual (a corresponding) first time point between the time points t2 and t5, and an erase inhibit voltage VEF may be applied to the word-lines of each of the word-line groups WGRa, WGRb, WGRc and WGRd from the individual (the corresponding) first time point. The erase inhibit voltage VEF may have a voltage level of a power supply voltage VDD. The word-line erase voltage VWE may be 0.3V and may be greater than the ground voltage. In example embodiments, a voltage level of the word-line erase voltage VWE may be different in each of the word-line groups WGRa, WGRb, WGRc and WGRd.

Therefore, an erase operation may be performed on memory cells coupled to the word-lines of each of the word-line groups WGRa, WGRb, WGRc and WGRd until the individual (the corresponding) first time point and the memory cells coupled to the word-lines of each of the word-line groups WGRa, WGRb, WGRc and WGRd may be erased. That is, when the sensed temperature is in the first temperature range, an erase operation may be performed on the word-lines of each of the word-line groups WGRa, WGRb, WGRc and WGRd during an erase execution time interval from the time point t2 to the individual (the corresponding) first time point.

When the sensed temperature is in the second temperature range, the erase voltage VERS, which is applied to a channel of the target memory block, may start to ramp at a time point t1, arrive at a target level TL2 at a time point t3, start to drop at a time point t4, and arrive at a ground voltage level at a time point at t6. The word-line erase voltage VWE may be applied to word-lines of each of the word-line groups WGRa, WGRb, WGRc and WGRd until an individual (a corresponding) second time point between the time points t3 and t4, and the erase inhibit voltage VEF may be applied to the word-lines of each of the word-line groups WGRa, WGRb, WGRc and WGRd from the individual (the corresponding) second time point.

Therefore, an erase operation may be performed on memory cells coupled to the word-lines of each of the word-line groups WGRa, WGRb, WGRc and WGRd until the individual (the corresponding) second time point and the memory cells coupled to the word-lines of each of the word-line groups WGRa, WGRb, WGRc and WGRd may be erased. That is, when the sensed temperature is in the second temperature range, an erase operation may be performed on the word-lines of each of the word-line groups WGRa, WGRb, WGRc and WGRd during an erase execution time interval from the time point t3 to the individual (the corresponding) second time point.

For example, when the sensed temperature is in the first temperature range, the erase operation may be performed on the word-lines of the word-line group WGRa during an erase execution time interval tERS1 from the time point t2 to a time point at which the erase inhibit voltage VEF is applied. When the sensed temperature is in the second temperature range, the erase operation may be performed on the word-lines of the word-line group WGRa during an erase execution time interval tERS2 from the time point t3 to a time point at which the erase inhibit voltage VEF is applied.

As each of reference numerals 61 and 63 indicates, the second time point may be earlier than the first time point in each of the word-line groups WGRa and WGRc. As each of reference numerals 62 and 64 indicates, the second time point may be later than the first time point in each of the word-line groups WGRb and WGRd. In addition, an adjusted amount of erase execution time interval for compensating for degradation of erase distribution generated by a change of the operating temperature may be different in each of the word-line groups WGRa, WGRb, WGRc and WGRd.

Performing the erase operation by applying the erase voltage VERS to the channel may be performed by using a gate induced drain leakage (GIDL). As understood from the name itself, the GIDL indicates a phenomenon that a leakage occurs at a drain of a transistor by a gate of the transistor. For example, when 0V or a negative voltage level is applied to the gate and a sufficiently high positive voltage is applied to the drain, severe band bending may be induced in the oxide near the drain and thus band-to-band tunneling from the valence band of the silicon surface to the conduction band of the silicon body may occur.

The tunneling elections are attracted to the drain and the drain current increases. Usually the semiconductor substrate is biased by a ground voltage, and holes are attracted to the semiconductor substrate of a relatively low voltage. The gate voltage of a negative voltage level is used to turn off the transistor, but the transistor may operate as if it is turned on because the drain current of the GIDL current increases due to the GIDL phenomenon. The GIDL current increases as the gate voltage is decreased and/or the drain voltage is increased.

The erase operation may be performed by using the GIDL phenomenon. For generating the GIDL phenomenon, a string selection transistor of a cell string, a ground selection transistor of a cell string, or a GIDL transistor may be used, which will be described with reference to FIGS. 14A, 14B, and 14C.

Therefore, in a method of operating a nonvolatile memory device according to example embodiments, the memory cells of the target memory block may be prevented from being over-erased in the cold temperature range by setting erase bias condition differently in the hot temperature condition and in the cold temperature condition.

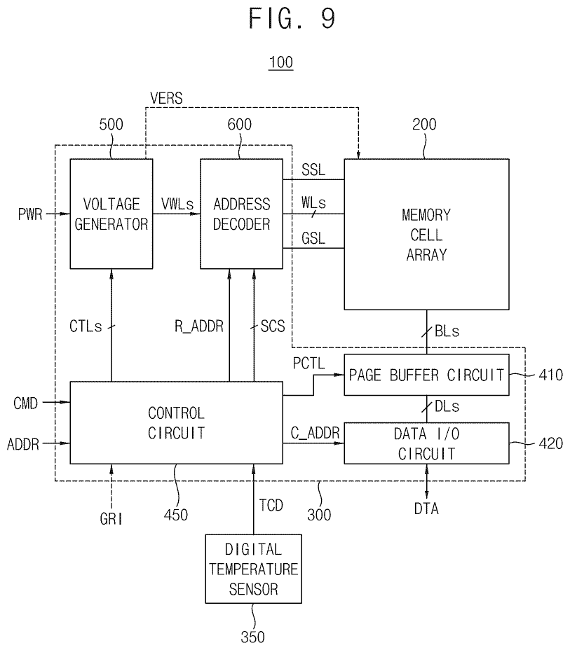

FIG. 7 is a block diagram illustrating a memory system according to example embodiments.

Referring to FIG. 7, a memory system (e.g., a storage device) 10 may include a memory controller 50 and a nonvolatile memory device 100.

In example embodiments, each of the memory controller 50 and the nonvolatile memory device 100 may be provided with the form of a chip, a package, or a module. In some embodiments, the memory controller 50 and the nonvolatile memory device 100 may be packaged into one of various packages.

The nonvolatile memory device 100 may perform an erase operation, a program operation or a read operation under control of the memory controller 50. The nonvolatile memory device 100 may receive a command CMD, an address ADDR and data DTA through input/output lines from the memory controller 50 for performing such operations. In addition, the nonvolatile memory device 100 may receive a control signal CTRL through a control line from the memory controller 50. In addition, the nonvolatile memory device 100 may receive a power PWR through a power line from the memory controller 50.

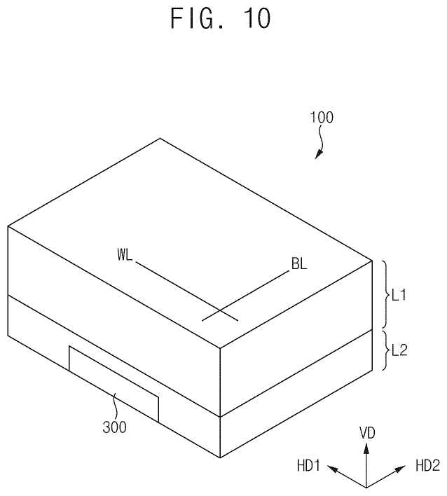

FIG. 8 is a block diagram illustrating an example of the memory controller in the memory system in FIG. 7 according to example embodiments.

Referring to FIG. 8, the memory controller 50 may include a processor 60, an error correction code (ECC) engine 70, an on-chip memory 80, an advanced encryption standard (AES) engine 90, a host interface 92, a read only memory (ROM) 94 and a memory interface 96 which are (electrically) connected via a bus 55.

The processor 60 may control an overall operation of the memory controller 50. The processor 60 may control the ECC engine 70, the on-chip memory 80, the AES engine 90, the host interface 92, the ROM 94 and the memory interface 96. The processor 60 may include one or more cores (e.g., a homogeneous multi-core or a heterogeneous multi-core). The processor 60 may be or include, for example, a central processing unit (CPU), an image signal processing unit (ISP), a digital signal processing unit (DSP), a graphics processing unit (GPU), a vision processing unit (VPU), and/or a neural processing unit (NPU). The processor 60 may execute various application programs (e.g., a flash translation layer (FTL) 81 and firmware) loaded onto the on-chip memory 80.

The on-chip memory 80 may store various application programs that are executable by the processor 60. The on-chip memory 80 may operate as a cache memory adjacent to the processor 60. The on-chip memory 80 may store a command, an address, and data to be processed by the processor 60 or may store a processing result of the processor 60. The on-chip memory 80 may be, for example, a storage medium or a working memory including a latch, a register, a static random access memory (SRAM), a dynamic random access memory (DRAM), a thyristor random access memory (TRAM), a tightly coupled memory (TCM), etc.

The processor 60 may execute the FTL 81 loaded onto the on-chip memory 80. The FTL 81 may be loaded onto the on-chip memory 80 as firmware or a program stored in the nonvolatile memory device 100. The FTL 81 may manage mapping between a logical address provided from a host and a physical address of the nonvolatile memory device 100 and may include an address mapping table manager managing and updating an address mapping table. The FTL 81 may further perform a garbage collection operation, a wear leveling operation, and the like, as well as the address mapping described above. The FTL 81 may be executed by the processor 60 for addressing one or more of the following aspects of the nonvolatile memory device 100: overwrite-or in-place write-impossible, a life time of a memory cell, a limited number of program-erase (PE) cycles, and an erase speed slower than a write speed. The FTL 81 may provide the nonvolatile memory device 100 mapping information between the logical address and the physical address.

Memory cells of the nonvolatile memory device 100 may have the physical characteristic that a threshold voltage distribution varies due to causes, such as a program elapsed time, a temperature, program disturbance, read disturbance and etc. For example, data stored at the nonvolatile memory device 100 may become erroneous due to the above causes.

The memory controller 50 may utilize a variety of error correction techniques to correct such errors. For example, the memory controller 50 may include the ECC engine 70. The ECC engine 70 may correct errors which occur in the data stored in the nonvolatile memory device 100. The ECC engine 70 may include an ECC encoder 71 and an ECC decoder 73. The ECC encoder 71 may perform an ECC encoding operation on data to be stored in the nonvolatile memory device 100. The ECC decoder 73 may perform an ECC decoding operation on data read from the nonvolatile memory device 100.

The ROM 94 may store a variety of information, needed for the memory controller 50 to operate, in firmware.

The AES engine 90 may perform at least one of an encryption operation and a decryption operation on data input to the memory controller 50 by using a symmetric-key algorithm. Although not illustrated in detail, the AES engine 90 may include an encryption module and a decryption module. For example, the encryption module and the decryption module may be implemented as separate modules. For another example, one module capable of performing both encryption and decryption operations may be implemented in the AES engine 90.

The memory controller 50 may communicate with the host through the host interface 92. For example, the host interface 92 may include Universal Serial Bus (USB), Multimedia Card (MMC), embedded-MMC, Peripheral Component Interconnection (PCI), PCI-express, Advanced Technology Attachment (ATA), Serial-ATA, Parallel-ATA, Small Computer Small Interface (SCSI), Enhanced Small Disk Interface (ESDI), Integrated Drive Electronics (IDE), Mobile Industry Processor Interface (MIPI), Nonvolatile memory express (NVMe), Universal Flash Storage (UFS), and etc. The memory controller 50 may communicate with the nonvolatile memory device 100 through the memory interface 96.

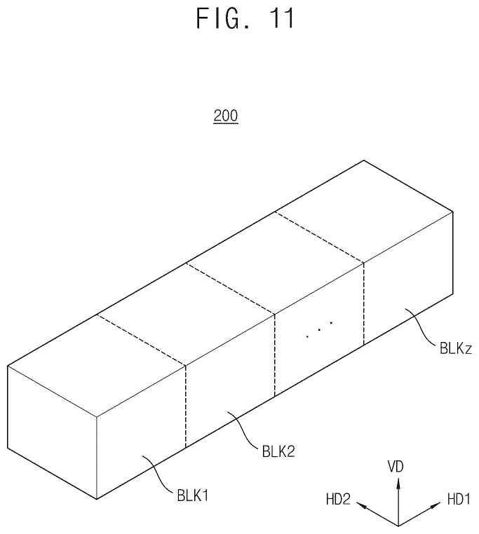

FIG. 9 is a block diagram illustrating an example of the nonvolatile memory device in the memory system of FIG. 7 according to example embodiments.

Referring to FIG. 9, the nonvolatile memory device 100 may include a memory cell array 200 and a peripheral circuit 300. The peripheral circuit 300 may include an address decoder 600, a page buffer circuit 410, a data input/output (I/O) circuit 420, a control circuit 450 and a voltage generator 500. In example embodiments, the nonvolatile memory device 100 may further include a digital temperature sensor 350. The digital temperature sensor 350 may be included in the peripheral circuit 300. The digital temperature sensor 350 may be disposed at an outside of the peripheral circuit 300.

The memory cell array 200 may be coupled (e.g., (electrically) connected) to the address decoder 600 through a string selection line SSL, a plurality of word-lines WLs, and a ground selection line GSL. In addition, the memory cell array 200 may be coupled (e.g., (electrically) connected) to the page buffer circuit 410 through a plurality of bit-lines BLs. The memory cell array 200 may include a plurality of nonvolatile memory cells coupled to (e.g., (electrically) connected) the plurality of word-lines WLs and the plurality of bit-lines BLs.

In some example embodiments, the memory cell array 200 may be a three-dimensional memory cell array, which is formed on a substrate in a three-dimensional structure (or a vertical structure). In this case, the memory cell array 200 may include vertical cell strings that are vertically oriented such that at least one memory cell is located over another memory cell.

The control circuit 450 may receive the command (signal) CMD and the address (signal) ADDR from the memory controller 50 and control an erase loop, a program loop and a read operation of the nonvolatile memory device 100 based on the command CMD and the address ADDR. The program loop may include a program operation and a program verification operation. The erase loop may include an erase operation and an erase verification operation.

For example, the control circuit 450 may generate control signals CTLs to control the voltage generator 500, may generate a control signal PCTL to control the page buffer circuit 410 and may generate a switching control signal SCS to control the address decoder 600 based on the command CMD, the digital temperature code TCD and word-line group information GRI. The control circuit 450 may provide the control signals CTLs to the voltage generator 500, may provide the control signal PCTL to the page buffer circuit 410 and may provide the switching control signal SCS to the address decoder 600. The word-line group information GRI may be determined based on erase distribution width of the word-lines of the target memory block when erase verification operation is performed on the target memory block. The word-line group information GRI may be determined based on word-lines having a large (a larger or the largest) variation of the erase distribution width.

In addition, the control circuit 450 may generate a row address R_ADDR and a column address C_ADDR based on the address ADDR. The control circuit 450 may provide the row address R_ADDR to the address decoder 600 and provide the column address C_ADDR to the data I/O circuit 420.

The address decoder 600 may be coupled (e.g., (electrically) connected) to the memory cell array 200 through the string selection line SSL, the plurality of word-lines WLs, and the ground selection line GSL. During the program operation or the read operation, the address decoder 600 may determine one of the plurality of word-lines WLs as a selected word-line and determine rest of the plurality of word-lines WLs except for the selected word-line as unselected word-lines based on the row address R_ADDR.

The voltage generator 500 may generate word-line voltages VWLs, which are required for the operation of the nonvolatile memory device 100, based on the control signals CTLs. The voltage generator 500 may receive the power PWR from the memory controller 50. The word-line voltages VWLs may be applied to the plurality of word-lines WLs through the address decoder 600.

For example, during the erase operation, the voltage generator 500 may apply an erase voltage VERS to a channel of cell strings of the target memory block, may apply an word-line erase voltage to word-lines of the target memory block and may apply an erase inhibit voltage to the word-lines of the target memory block. During the erase verification operation, the voltage generator 500 may apply an erase verification voltage to the word-lines of the target memory block or sequentially apply the erase verification voltage to the word-lines on a word-line basis.

For example, during the program operation, the voltage generator 500 may apply a program voltage to the selected word-line and may apply a program pass voltage to the unselected word-lines. In addition, during the program verification operation, the voltage generator 500 may apply a program verification voltage to the selected word-line and may apply a verification pass voltage to the unselected word-lines. In addition, during the read operation, the voltage generator 500 may apply a read voltage to the selected word-line and may apply a read pass voltage to the unselected word-lines.

The page buffer circuit 410 may be coupled (e.g., (electrically) connected) to the memory cell array 200 through the plurality of bit-lines BLs. The page buffer circuit 410 may include a plurality of page buffers. The page buffer circuit 410 may temporarily store data to be programmed in a selected page or data read out from the selected page.

The data I/O circuit 420 may be coupled (e.g., (electrically) connected) to the page buffer circuit 410 through a plurality of data lines DLs. During the program operation, the data I/O circuit 420 may receive program data DTA from the memory controller 50 and provide the program data DTA to the page buffer circuit 410 based on the column address C_ADDR received from the control circuit 450. During the read operation, the data I/O circuit 420 may provide read data DTA, which are stored in the page buffer circuit 410, to the memory controller 50 based on the column address C_ADDR received from the control circuit 450.

The digital temperature sensor 350 may sense operating temperature of the nonvolatile memory device 100 and may provide the control circuit 450 with a digital temperature code TCD corresponding to the sensed operating temperature based on the sensed operating temperature. In some embodiments, values of the digital temperature code TCD may be proportional or inversely proportional to the sensed temperature.

The control circuit 450 may perform operations in FIGS. 1 through 5 by controlling the voltage generator 500 and the address decoder 600.

The control circuit 450 may control an erase operation on the target memory by adjusting erase execution time interval of each of word-lines of the target memory block, individually (respectively), based on the digital temperature code TCD which indicates the sensed temperature.

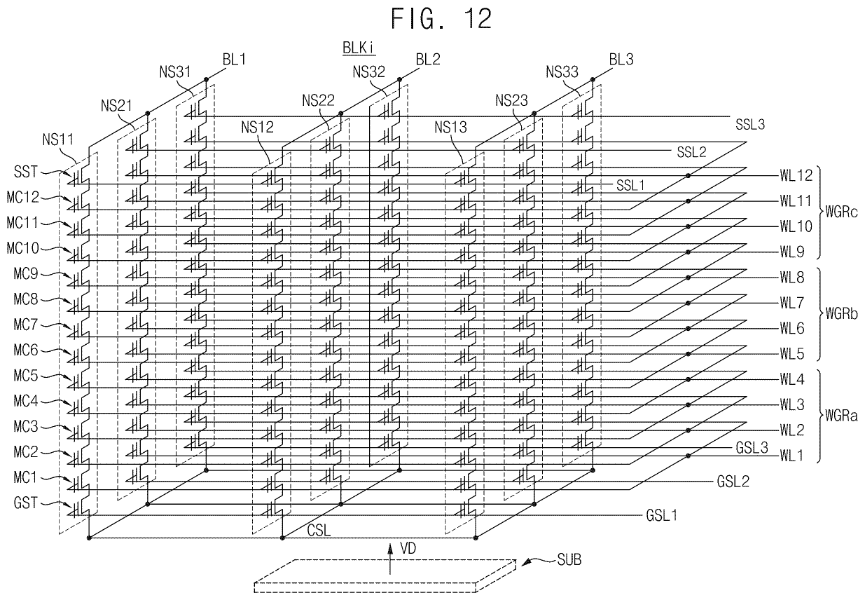

FIG. 10 schematically illustrates a structure of the nonvolatile memory device of FIG. 9 according to example embodiments.

Referring to FIG. 10, the nonvolatile memory device 100 may include a first semiconductor layer L1 and a second semiconductor layer L2, and the first semiconductor layer L1 may be stacked in a vertical direction VD with respect to the second semiconductor layer L2. The second semiconductor layer L2 may be under the first semiconductor layer L1 in the vertical direction VD, and accordingly, the second semiconductor layer L2 may be close (closer than the first semiconductor layer L1) to a substrate.

In example embodiments, the memory cell array 200 in FIG. 9 may be formed (or, provided) on (in) the first semiconductor layer L1, and the peripheral circuit 300 in FIG. 9 may be formed (or, provided) on (in) the second semiconductor layer L2. Accordingly, the nonvolatile memory device 100 may have a structure in which the memory cell array 200 is on the peripheral circuit 300, that is, a cell over periphery (COP) structure. The COP structure may effectively reduce an area in a horizontal direction and improve the degree of integration of the nonvolatile memory device 100.

In example embodiments, the second semiconductor layer L2 may include the substrate, and by forming transistors on the substrate and metal patterns for wiring transistors, the peripheral circuit 300 may be formed in the second semiconductor layer L2. After the peripheral circuit 300 is formed on (in) the second semiconductor layer L2, the first semiconductor layer L1 including the memory cell array 200 may be formed, and the metal patterns for (electrically) connecting the word-lines WL and the bit-lines BL of the memory cell array 200 to the peripheral circuit 300 formed in the second semiconductor layer L2 may be formed. For example, the word-lines WL may extend in a first horizontal direction HD1 and the bit-lines BL may extend in a second horizontal direction HD2.

As the number of stages of memory cells in the memory cell array 200 increases with the development of semiconductor processes, that is, as the number of stacked word-lines WL increases, an area of the memory cell array 200 may decrease, and accordingly, an area of the peripheral circuit 300 may also be reduced. According to an embodiment, to reduce an area of a region occupied by the page buffer circuit 410, the page buffer circuit 410 may have a structure in which the page buffer unit and the cache latch are separated from each other, and may connect sensing nodes included in each of the page buffer units commonly to a combined sensing node.

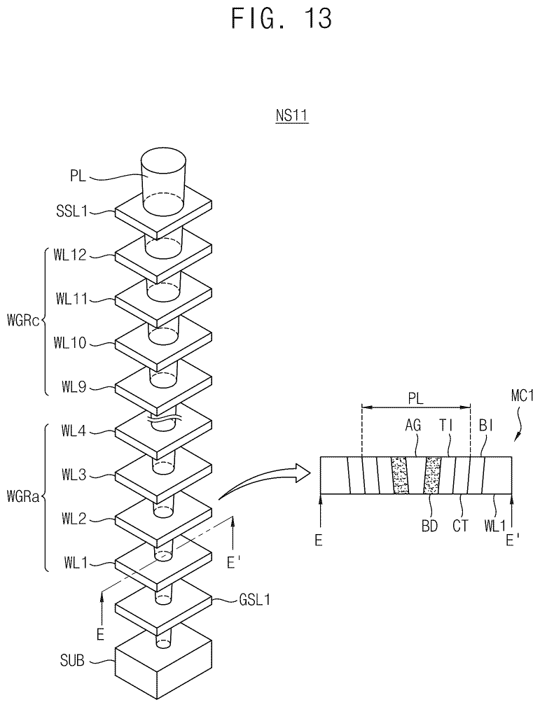

FIG. 11 is a block diagram illustrating an example of the memory cell array in the nonvolatile memory device of FIG. 9 according to example embodiments.

Referring to FIG. 11, the memory cell array 200 may include a plurality of memory blocks BLK1, BLK2 to BLKz. Here, z is a natural number greater than two. The memory blocks BLK1, BLk2 to BLKz may extend along the first horizontal direction HD1, the second horizontal direction HD2, and the vertical direction VD. In some example embodiments, the memory blocks BLK1, BLK2 to BLKz may be selected by the address decoder 600 in FIG. 9. For example, the address decoder 600 may select a memory block BLK corresponding to a block address among the memory blocks BLK1, BLK2 to BLKz.

The first horizontal direction HD1 and the second horizontal direction HD2 may intersect (cross) each other and are (substantially) parallel to an upper surface to a substrate (or the second semiconductor layer L2) and the vertical direction VD may be (substantially) perpendicular to the upper surface of the substrate (or the second semiconductor layer L2). In some embodiments, the first horizontal direction HD1 and the second horizontal direction HD2 may be (substantially) perpendicular to each other.

FIG. 12 is a circuit diagram illustrating one of the memory blocks of FIG. 11 according to example embodiments.

A memory block BLKi of FIG. 12 may be formed on a substrate SUB in a three-dimensional structure (or a vertical structure). Here, i may be a natural number among from 1 to z. The memory block BLKi may be one among the memory blocks BLK1, BLK2 to BLKz. For example, a plurality of memory cell strings included in the memory block BLKi may be formed in the vertical direction VD perpendicular to the substrate (the substrate SUB).

Referring to FIG. 12, the memory block BLKi may include a plurality of (memory) cell strings NS11, NS21, NS31, NS12, NS22, NS32, NS13, NS23, and NS33 coupled ((electrically) connected) between bit-lines BL1, BL2 and BL3 and a common source line CSL. The plurality of cell strings NS11, NS21, NS31, NS12, NS22, NS32, NS13, NS23, and NS33, herein may be referred to as (memory) cell strings NS11 to NS33. Each of the cell strings NS11 to NS33 may include a string selection transistor SST, a plurality of memory cells MC1 to MC12, and a ground selection transistor GST. In FIG. 12, each of the cell strings NS11 to NS33 is illustrated to include twelve memory cells MC1 to MC12. However, embodiments are not limited thereto. In some example embodiments, each of the cell strings NS11 to NS33 may include any number of memory cells.

The string selection transistor SST may be (electrically) connected to corresponding string selection lines SSL1, SSL2 and SSL3. The plurality of memory cells MC1 to MC12 may be (electrically) connected to corresponding word-lines WL1, WL2, WL3, WLA, WL5, WL6, WL7, WL8, WL9, WL10, WL11 and WL12 (hereinafter WL1 to WL12), respectively. The ground selection transistor GST may be (electrically) connected to corresponding ground selection lines GSL1, GSL2 and GSL3. The string selection transistor SST may be (electrically) connected to corresponding bit-lines BL1, BL2 and BL3, and the ground selection transistor GST may be (electrically) connected to the common source line CSL.

Word-lines (e.g., word-line WL1) having the same height may be commonly connected, and the ground selection lines GSL1, GSL2 and GSL3 and the string selection lines SSL1, SS12 and SSL3 may be separated. In FIG. 12, the memory block BLKi is illustrated to be coupled ((electrically) connected) to twelve word-lines WL1 to WL12 and three bit-lines BL1, BL2 and BL3.

The control circuit 450 in FIG. 9 may divide the plurality of word-lines WL1 to WL12 into a plurality of word-line groups WGRa, WGRb and WGRc based on a distance in the vertical direction VD from the common source line CSL. For example, the word-line group WGRa may include the word-lines WL1, WL2, WL3 and WL4, the word-line group WGRb may include the word-lines WL5, WL6, WL7 and WL8, and the word-line group WGRc may include the word-lines WL9, WL10, WL11 and WL12. In example embodiments, a number of word-lines in each of the word-line groups WGRa, WGRb and WGRc may be different.

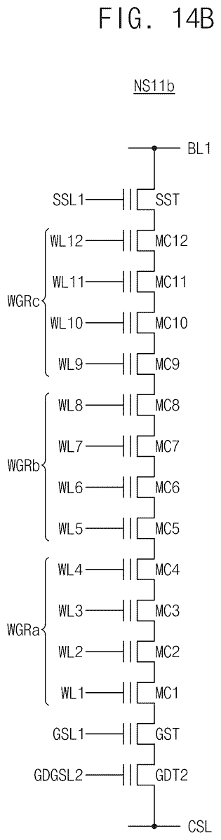

FIG. 13 illustrates an example of a structure of a cell string (e.g., NS11) in the memory block of FIG. 12.

Referring to FIGS. 12 and 13 a pillar PL may be provided on the substrate SUB such that the pillar PL extends in a direction (e.g., the vertical direction VD) perpendicular to the substrate SUB to make contact with the substrate SUB. Each of the ground selection line GSL (GSL1), the word-lines WL1 to WL12, and the string selection lines SSL (SSL1) in FIG. 13 may include (e.g., may be formed of) a conductive material, for example, a metallic material. The pillar PL may be in contact with the substrate SUB through the conductive materials forming the string selection lines SSL, the word-lines WL1 to WL12, and the ground selection line GSL. the word-line group WGRa may include the word-lines WL1, WL2, WL3 and WL4, and the word-line group WGRc may include the word-lines WL9, WL10, WL11 and WL12. Although omitted in FIG. 13, the word-line group WGRb including the word-lines WL5, WL6, WL7, and WL8 may be positioned between the word-line group WGRa and the word-line group WGRc in the vertical direction VD.

A sectional view taken along a line E-E′ is also illustrated in FIG. 13. In some example embodiments, a sectional view of a first memory cell MC1 corresponding to a first word-line WL1 is illustrated. The pillar PL may include a cylindrical body BD. An air gap AG may be defined in the interior of the body BD.

The body BD may include P-type silicon and may be an area where a channel will be formed. The pillar PL may further include a cylindrical tunnel insulating layer TI extending around (e.g., surrounding) the body BD and a cylindrical charge trap layer CT extending around (e.g., surrounding) the tunnel insulating layer TI. A blocking insulating layer BI may be provided between the first word-line WL1 and the pillar PL. For example, the blocking insulating layer BI may extend around (e.g., surround) the charge trap layer CT. The body BD, the tunnel insulating layer TI, the charge trap layer CT, the blocking insulating layer BI, and the first word-line WL1 may constitute or be included in a charge trap type transistor that is formed in a direction (e.g., the vertical direction VD) perpendicular to the substrate SUB or to an upper surface of the substrate SUB. A string selection transistor SST, a ground selection transistor GST, and other memory cells (e.g., memory cells MC2 to MC12) may have a similar structure or the same structure as the first memory cell MC1.

FIGS. 14A, 14B, and 14C illustrate examples of one of cell strings (NS11) in FIG. 13, respectively, according to example embodiments.

In each of FIGS. 14A, 14B, and 14C, the word-line group WGRa may include the word-lines WL1, WL2, WL3 and WL4, the word-line group WGRb may include the word-lines WL5, WL6, WL7 and WL8, and the word-line group WGRc may include the word-lines WL9, WL10, WL11 and WL12.

Referring to FIG. 14A, a cell string NS11a may include a ground selection transistor GST, a plurality of memory cells MC1 to MC12, a string selection transistor SST and a GIDL string selection transistor GDT1 (electrically) connected in series between the common source line CSL and the bit-line BL1. The GIDL string selection transistor GDT1 may be coupled ((electrically) connected) to a GIDL string selection line GDSSL1. The GIDL phenomenon may be generated at the GIDL string selection transistor GDT1 by applying a GIDL-on voltage to the GIDL string selection line GDSSL1 such that (at least) a portion of the memory cells MC1 to MC12 are erased. The GIDL-on voltage may correspond to a voltage having a level to turn-on the GIDL string selection transistor GDT1. Each of the (memory) cell strings NS11 to NS33 in FIG. 12 may employ the cell string NS11a of FIG. 14A.

Referring to FIG. 14B, a cell string NS11b may include a GIDL ground selection transistor GDT2, a ground selection transistor GST, a plurality of memory cells MC1 to MC12 and a string selection transistor SST (electrically) connected in series between the common source line CSL and the bit-line BL1. The GIDL ground selection transistor GDT2 may be coupled ((electrically) connected) to a GIDL ground selection line GDGSL2. The GIDL phenomenon may be generated at the GIDL ground selection transistor GDT2 by applying a GIDL-on voltage to the GIDL ground selection line GDGSL2 such that (at least) a portion of the memory cells MC1 to MC12 are erased. Each of the (memory) cell strings NS11 to NS33 in FIG. 12 may employ the cell string NS11b of FIG. 14B.

Referring to FIG. 14C, a cell string NS11c may include a GIDL ground selection transistor GDT2, a ground selection transistor GST, a plurality of memory cells MC1 to MC12, a string selection transistor SST and a GIDL string selection transistor GDT1 (electrically) connected in series between the common source line CSL and the bit-line BL1. The GIDL ground selection transistor GDT2 may be coupled ((electrically) connected) to a GIDL ground selection line GDGSL2 and the GIDL string selection transistor GDT1 may be coupled ((electrically) connected) to a GIDL string selection line GDSSL1. The GIDL phenomenon may be generated at the GIDL string selection transistor GDT1 and the GIDL ground selection transistor GDT2 by applying a GIDL-on voltage to the GIDL string selection line GDSSL1 and the GIDL ground selection line GDGSL2 such that (at least) a portion of the memory cells MC1 to MC12 are erased. Each of the (memory) cell strings NS11 to NS33 in FIG. 12 may employ the cell string NS11c of FIG. 14C.

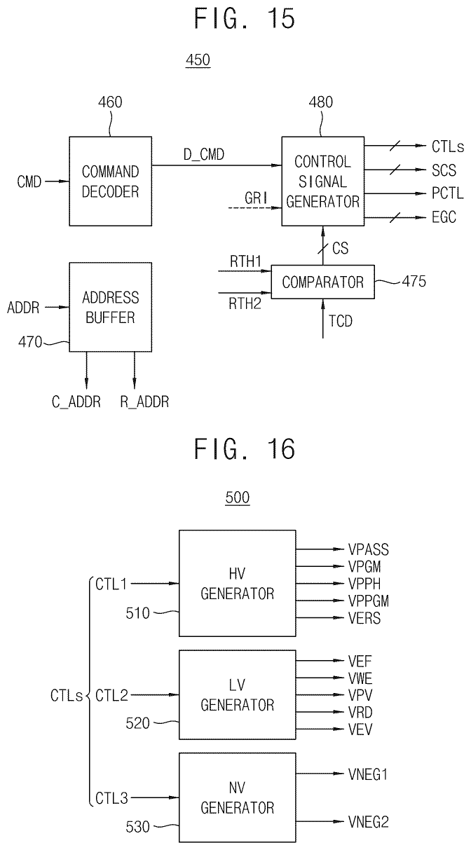

FIG. 15 is a block diagram illustrating the control circuit in the nonvolatile memory device of FIG. 9 according to example embodiments.

Referring to FIG. 15, the control circuit 450 may include a command decoder 460, an address buffer 470, a comparator 475 and a control signal generator 480.

The command decoder 460 may decode the command CMD and may provide a decoded command D_CMD to the control signal generator 480.

The address buffer 470 may receive the address (signal) ADDR, provide the row address R_ADDR to the address decoder 600 and provide the column address C_ADDR to the data I/O circuit 420.

The comparator 475 may compare the digital temperature code TCD with a first reference temperature RTH1 and a second reference temperature RTH2 and may provide the control signal generator 480 with a comparison signal CS indicating a result of the comparison. The comparison signal CS may include a plurality of bits, may indicate whether the digital temperature code TCD is greater than the first reference temperature RTH1 and may indicate whether the digital temperature code TCD is smaller than the second reference temperature RTH2.

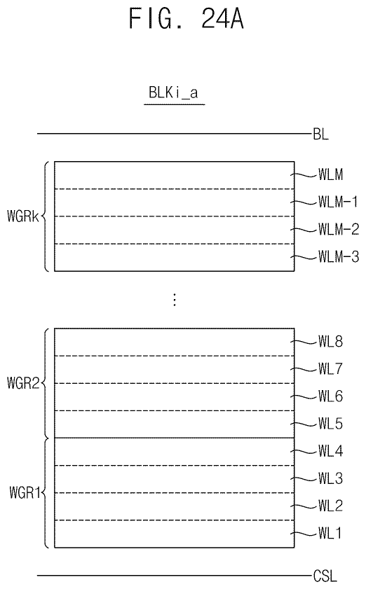

The control signal generator 480 may receive the decoded command D_CMD and the comparison signal CS, based on at least one of an operation directed by the decoded command D_CMD and the comparison signal CS, generate the control signals CTLs based on at least one of an operation directed by the decoded command D_CMD and the comparison signal CS, provide the control signals CTLs to the voltage generator 500, generate the control signal PCTL, provide the control signal PCTL to the page buffer circuit 410, generate the switching control signal SCS, provide the switching control signal SCS to the address decoder 600, generate an erase control signal EGC and provide the erase control signal EGC to erase transistors (ERT1 and ERT2 in FIG. 23). The control signal generator 480 may generate the control signals CTLs and the switching control signal SCS further based on the word-line group information GRI.

When the decoded command D_CMD designates an erase operation, the control signal generator 480 may generate the switching control signal SCS based on the comparison signal CS. The control circuit 450 may determine time point of applying an erase inhibit voltage to the word-lines of the target memory block by the switching control signal SCS.

When the decoded command D_CMD designates the erase operation and when the comparison signal CS indicates that the sensed temperature is equal to or greater than the first reference temperature RTH1, (e.g., when the comparison signal CS indicates that the sensed temperature is in the first temperature range), the control signal generator 480 may generate the control signals CTLs and the switching control signal SCS such that the word-lines of the target memory block is erased during an execution time interval based on a first erase bias condition.

When the decoded command D_CMD designates the erase operation and when the comparison signal CS indicates that the sensed temperature is equal to or smaller than the second reference temperature RTH2, (e.g., when the comparison signal CS indicates that the sensed temperature is in the second temperature range), the control signal generator 480 may generate the control signals CTLs and the switching control signal SCS such that the word-lines of the target memory block is erased during an execution time interval based on a second erase bias condition.

The control circuit 450 may divide word-lines of the target memory block into a plurality of word-line groups based on the word-line group information GRI and the distance in the vertical direction from the common source line CSL. The control circuit 450, in response to the sensed temperature being in the first temperature range (equal to or) greater than the first reference temperature RTH1 among a plurality of temperature ranges, may set the first erase bias condition corresponding to the first temperature range and may perform the first erase operation on the target memory block based on the first erase bias condition (refer to FIGS. 3 and 4). Based on the first erase bias condition, the control circuit 450 may control the voltage generator 500 and the address decoder 600 to perform the first erase operation by applying the erase voltage having a first target level to a channel of the target memory block during an erase execution (time) period, applying the word-line erase voltage to the word-lines of the target memory block while the erase voltage having the first target level is applied and applying the erase inhibit voltage to word-lines in each of the word-line groups at an individual (a corresponding) first time point in the erase execution (time) period.

The control circuit 450, in response to the sensed temperature being in the second temperature range (equal to or) smaller than the second reference temperature RTH2 among the plurality of temperature ranges, may set the second erase bias condition corresponding to the second temperature range and may perform the second erase operation on the target memory block based on the second erase bias condition (refer to FIGS. 3 and 5). Based on the second erase bias condition, the control circuit 450 may control the voltage generator 500 and the address decoder 600 to perform the second erase operation by applying the erase voltage having a second target level to a channel of the target memory block during an erase execution (time) period, applying a word-line erase voltage to the word-lines of the target memory block while the erase voltage having the second target level is applied and applying the erase inhibit voltage to word-lines in each of the word-line groups at an individual (a corresponding) second time point in the erase execution (time) period.

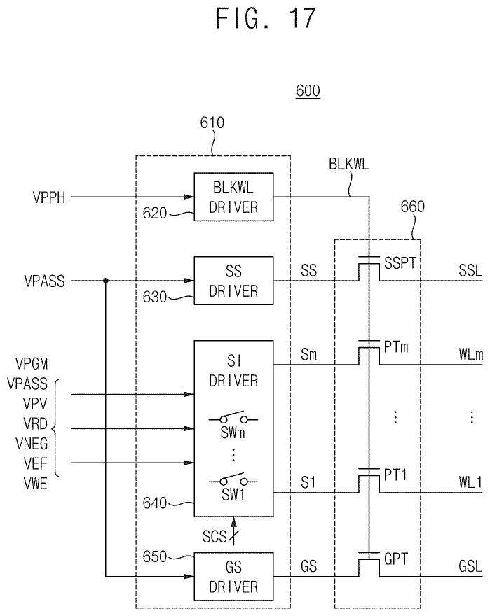

FIG. 16 is a block diagram illustrating the voltage generator in the nonvolatile memory device of FIG. 9 according to example embodiments.

Referring to FIG. 16, the voltage generator 500 may include a high voltage (HV) generator 510 and a low voltage (LV) generator 520. The voltage generator 500 may further include a negative voltage (NV) generator 530.

The high voltage generator 510 may generate a program voltage VPGM, a high voltage VPPH, a pass voltage VPASS, a verification pass voltage VVPASS, a read pass voltage VRPASS, a pre-program voltage VPPGM and an erase voltage VERS according to operations directed by the command CMD, in response to a first control signal CTL1. The pass voltage VPASS may include a program pass voltage, a verification pass voltage (the verification pass voltage VVPASS), and a read pass voltage (the read pass voltage VRPASS).

The program voltage VPGM may be applied to the selected word-line, the pass voltage VPASS may be applied to the unselected word-lines, the pre-program voltage VPPGM may be applied to the word-lines of the target memory block, the erase voltage VERS may be applied to a channel through erase transistors (ERT1 and ERT2 in FIG. 23) and the high voltage VPPH may be applied to a gate of each of pass transistors coupled to word-lines, a string selection line (SSL) and a ground selection line (GSL). The first control signal CTL1 may include a plurality of bits which indicate the operations directed by the decoded command D_CMD.

The low voltage generator 520 may generate an erase inhibit voltage VEF, a word-line erase voltage VWE, a program verification voltage VPV, a read voltage VRD and an erase verification voltage VEV according to operations directed by the command CMD, in response to a second control signal CTL2.

The erase inhibit voltage VEF and the word-line erase voltage VWE may be applied to the word-lines of the target memory block. The program verification voltage VPV, the read voltage VRD, and the erase verification voltage VEV may be applied to the word-lines of the target memory block. The second control signal CTL2 may include a plurality of bits which indicate the operations directed by the decode command D_CMD.

The negative voltage generator 530 may generate a first negative voltage VNEG1 and a second negative voltage VNEG2 which have negative levels according to operations directed by the command CMD, in response to a third control signal CTL3. The third control signal CTL3 may include a plurality of bits which indicate the operations directed by the decoded command D_CMD. The first negative voltage VNEGI and the second negative voltage VNEG2 may be used for the program operation.

Therefore, the control circuit 450 in FIG. 9 may receive the erase command and the block address designating the target memory block among the plurality of memory blocks and may control the voltage generator 500 and the address decoder 600 to control the erase operation on the target memory block by adjusting erase execution time interval of each of the word-lines of the target memory block, individually (respectively), based on the sensed temperature.

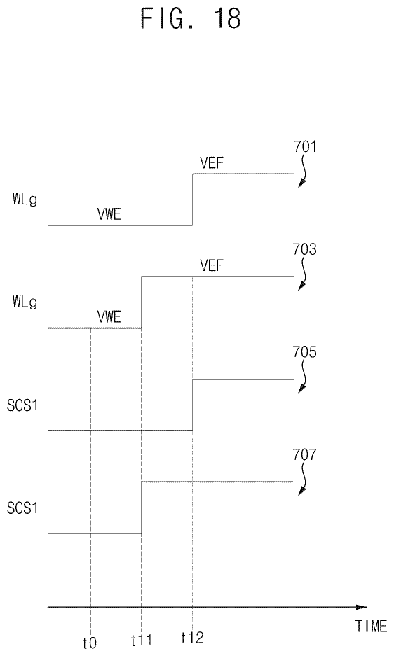

FIG. 17 is a block diagram illustrating an example of the address decoder in the nonvolatile memory device of FIG. 9 according to example embodiments.

Referring to FIG. 17, the address decoder 600 may include a driver circuit 610 and a pass transistor circuit 660.

The driver circuit 610 may transfer voltages provided from the voltage generator 500 to the memory cell array 200 in response to a block address. The driver circuit 610 may include a block selection driver (BLKWL DRIVER) 620, a string selectin driver (SS DRIVER) 630, a driving line driver (SI DRIVER) 640 and a ground selection driver (GS DRIVER) 650.

The block selection driver 620 may supply the high voltage VPPH from the voltage generator 500 to the pass transistor circuit 660 in response to the block address. The block selection driver 620 may supply the high voltage VPPH to a block word-line BLKWL coupled ((electrically) connected) to gates of a plurality of pass transistors GPT, PT1 to PTm and SSPT in the pass transistor circuit 660. Herein, m may be a natural number greater than one. The block selection driver 620 may control the application of various voltages such as a pass voltage, a program voltage, a read voltage to the memory cell array 200.

The string selection driver 630 may supply voltage (for example, pass voltage VPASS) from the voltage generator 500 to the string selection line SSL through the pass transistor SSPT as a string selection signal SS. During the program operation, the string selection driver 630 may supply the string selection signal SS so as to turn on all string selection transistors in a selected memory block.

The driving line driver 640 may supply the program voltage VPGM, the pass voltage VPASS, the verification voltage VPV, the read voltage VRD, the erase inhibit voltage VEF, the word-line erase voltage VWE and a negative voltage VNEG from the voltage generator 500 to the word-lines WL1 to WLm through driving lines S1 to Sm and the pass transistors PT1 to PTm. Herein, m may be a natural number greater than one.

The driving line driver 640 may include a plurality of switches SW1 to SWm that transfer a portion of the program voltage VPGM, the pass voltage VPASS, the verification voltage VPV, the read voltage VRD, the erase inhibit voltage VEF, the word-line erase voltage VWE and the negative voltage VNEG to the driving lines S1 to Sm in response to the switching control signal SCS.

The ground selection driver 650 may supply voltage (for example, pass voltage VPASS) from the voltage generator 500 to the ground selection line GSL through the pass transistor GPT as a ground selection signal GS.

The pass transistors GPT, PTI to PTm, and SSPT may be configured such that the ground selection line GSL, the word-lines WL1 to WLm, and the string selection line SSL are (electrically) connected to corresponding driving lines, in response to activation of the high voltage VPPH on the block word-line BLKWL. In example embodiments, each of the pass transistors GPT, PT1 to PTm, and SSPT may include a high voltage transistor capable of enduring high-voltage.

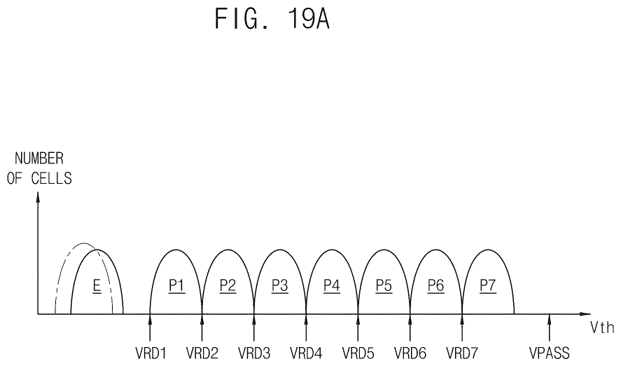

FIG. 18 illustrates an example operation of one of the plurality of switches in the address decoder of FIG. 17 according to example embodiments.

Referring to FIG. 18, when the sensed temperature is in the first temperature range, a switching control signal SCSI applied to a switch corresponding to a word-line WLg may be activated at a time point t12 as a reference numeral 705 indicates. Therefore, the word-line erase voltage VWE may be applied to the word-line WLg until the time point t12 and the erase inhibit voltage VEF may be applied to the word-line WLg from the time point t12 as a reference numeral 701 indicates. Herein, the word-line WLg may be one among the word-lines WL1 to WLm.

When the sensed temperature is in the second temperature range, the switching control signal SCS1 applied to a switch corresponding to the word-line WLg may be activated at a time point t11 as a reference numeral 707 indicates. Therefore, the word-line erase voltage VWE may be applied to the word-line WLg until the time point t11 and the erase inhibit voltage VEF may be applied to the word-line WLg from the time point t11 as a reference numeral 703 indicates.

Therefore, when the sensed temperature is in the first temperature range, the erase operation may be performed on the word-line WLg from a time point t10 to the time point t12. When the sensed temperature is in the second temperature range, the erase operation may be performed on the word-line WLg from the time point t10 to the time point t11. That is, erase execution time interval performed on the word-line WLg may be different based on the sensed temperature.

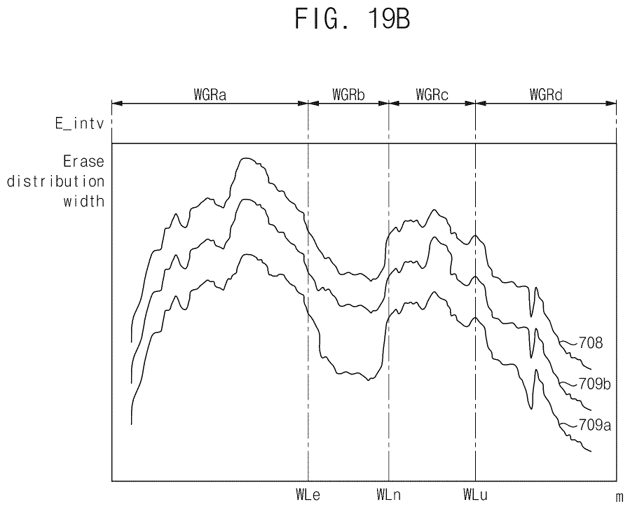

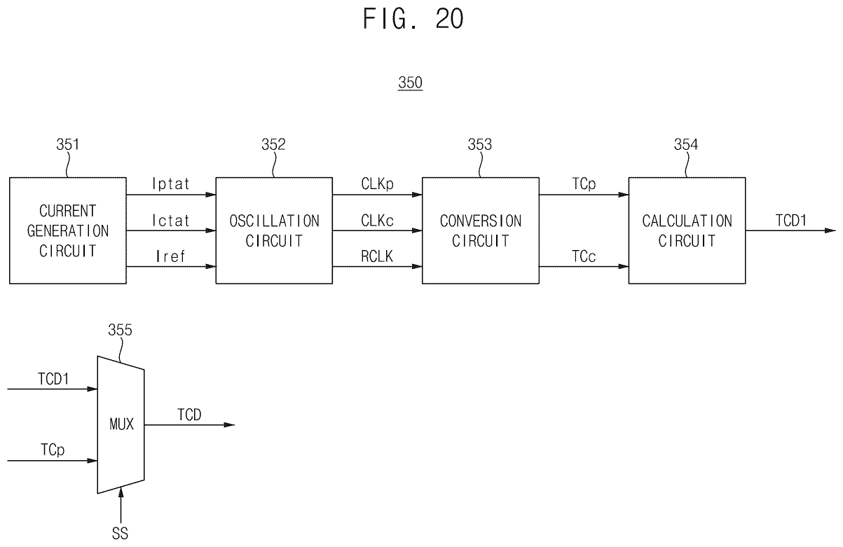

FIG. 19A is a graph showing a threshold voltage distributions of memory cells in FIG. 12.

In FIG. 19A, a horizontal axis represents a threshold voltage Vth and the vertical axis represents the number of memory cells.

Below, to describe embodiments of the present disclosure easily, it is assumed that each of the memory cells of the nonvolatile memory device 100 is a triple level cell (TLC) configured to store 3-bit data. However, the present disclosure is not limited thereto. For example, each memory cell may be a single level cell (SLC) storing 1-bit data, or a multi-level cell (MLC), a triple level cell (TLC), a quad level cell (QLC) or a penta level cell (PLC) storing q-bit data (q being a natural number greater than 1).

Referring to FIGS. 12 and 19A, each memory cell may be programmed to have one of an erase state “E” and first to seventh program states P1 to P7. To read data programmed in the memory cells, the nonvolatile memory device 100 may use a plurality of read voltages VRD1, VRD2, VRD3, VRD4, VRD5, VRD6 and VRD7 and a (read) pass voltage VPASS. For example, to read data programmed in memory cells (electrically) connected with a selected word-line, the nonvolatile memory device 100 may sequentially apply the plurality read voltages VRD1, VRD2, VRD3, VRD4, VRD5, VRD6 and VRD7 to the selected word-line and may apply the (read) pass voltages VPASS to the unselected word-lines. A voltage level of the (read) pass voltages VPASS may be greater than voltage levels of the read voltages VRD1, VRD2, VRD3, VRD4, VRD5, VRD6 and VRD7.

Threshold voltage distribution of the erase state “E” may be varied based on the operating temperature. When the same erase bias condition is applied to the target memory block under the first temperature range and the second temperature range, the memory cells may be over-erased as indicated by dotted lines and threshold voltage distribution of the erase state “E” may be degraded.

The memory cells having erase state “E” may have erase distribution width. As the erase distribution width becomes greater, a number of memory cells that are over-erased may increase. The over-erased memory cells degrade retention characteristic of adjacent memory cells, and thus, reliability of the nonvolatile memory device (the nonvolatile memory device 100) may be degraded as the erase distribution width (e.g., the erase dispersion range) becomes greater.

FIG. 19B illustrates an erase distribution width of a plurality of word-lines.

A horizontal axis of FIG. 19B may be defined as a stacking order of the plurality of word-lines WLI to WLm with respect to the substrate SUB or the common source line CSL, and a vertical axis of FIG. 19B may be defined as the erase distribution width E_intv.

As the stacking order increases from the lower end portion of the plurality of word-lines WL1 to WLm, the erase distribution width E_intv may (generally) increase (in the word-line group WGRa), as the stacking order increases with respect to an e-th word line WLe, the erase distribution width E_intv may rapidly (generally) decrease (in the word-line group WGRb), as the stacking order increases with respect to an n-th word line WLn, the erase distribution width E_intv rapidly (generally) increases (in the word-line group WGRc), and as the stacking order increases with respect to an u-th word line WLu, the erase distribution width E_intv rapidly (generally) decreases (in the word-line group WGRd). Here e is greater than 3 and less than n, and u is greater than n+1 and less than m−1.

The word-line group WGRa may include a plurality of word-lines continuously disposed from a first word-line WLI to the e-th word line WLe, the word-line group WGRb may include a plurality of word-lines continuously disposed from the e+1-th word line WLe+1 to the n-th word line WLn, the word-line group WGRc may include a plurality of word-lines continuously disposed from the n+1-th word line WLn+1 to the u-th word-line WLu the word-line group WGRd may include a plurality of word-lines continuously disposed from the u+1-th word line Wlu+1 to the m-th word-line WLm. In addition, the word-line group WGRd is disposed higher in the vertical direction VD from the substrate SUB or the common source line CSL than the word-line groups WGRa, WGRb and WGRc so that the thickness in the second horizontal direction with respect to a vertical insulation layer of the memory cell in the word-line group WGRd may be greater than the thickness in the second horizontal direction with respect to the vertical insulation layer of the memory cells in the word-line groups WGRa, WGRb and WGRc.

In FIG. 19B, a reference numeral 708 indicates the erase distribution width E_intv of the word-lines WL1 to WLm when the sensed temperature is in the first temperature range and when the erase operation is performed on the word-lines WL1 to WLm based on the first erase bias condition, a reference numeral 709a indicates the erase distribution width E_intv of the word-lines WL1 to WLm when the sensed temperature is in the second temperature range and when the erase operation is performed on the word-lines WL1 to WLm based on the first erase bias condition, and a reference numeral 709b indicates the erase distribution width E_intv of the word-lines WL1 to WLm when the sensed temperature is in the second temperature range and when the erase operation is performed on the word-lines WL1 to WLm based on the second erase bias condition different from the first erase bias condition. When the sensed temperature is in the second temperature range, it is noted that the erase distribution width E_intv of the word-lines WL1 to WLm decreases when the erase operation is performed on the word-lines WL1 to WLm based on an erase bias condition different from the first erase bias condition.

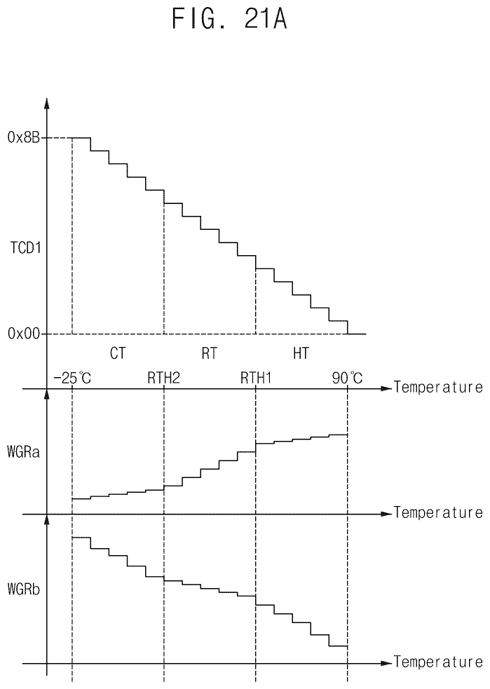

FIG. 20 is a block diagram illustrating an example of a digital temperature sensor in the nonvolatile memory device of FIG. 9 according to example embodiments.

Referring to FIG. 20, the digital temperature sensor 350 may include a current generation circuit 351, an oscillation circuit 352, a conversion circuit 353, a calculation circuit 354, and a multiplexer 355.

The current generation circuit 351 may generate a proportional to absolute temperature (PTAT) current Iptat that is proportional to the operation temperature and may generate a complementary to absolute temperature CTAT current Ictat that is inversely proportional to the operation temperature.

In example embodiments, the current generation circuit 351 may be implemented with a bandgap reference circuit configured to generate, in addition to the PTAT current Iptat and the CTAT current Ictat, a reference current Iref that is fixed regardless of the operation temperature.

The oscillation circuit 352 may generate a first clock signal CLKp having a first cyclic period based on the PTAT current Iptat such that the first cyclic period may be inversely proportional to the PTAT current Iptat. In addition, the oscillation circuit 352 may generate a second clock signal CLKc having a second cyclic period based on the CTAT current Ictat such that the second cyclic period may be inversely proportional to the CTAT current Ictat. In example embodiments, the oscillation circuit 352 may further generate, in addition to the first clock signal CLKp and the second clock signal CLKc, a reference clock signal RCLK having a reference cyclic period that is fixed regardless of the operation temperature based on the reference current Iref.

The conversion circuit 353 may generate a first temperature code TCp based on the first clock signal CLKp such that the first temperature code TCp may decrease as the operation temperature increases. In addition, the conversion circuit 353 may generate a second temperature code TCc based on the second clock signal CLKc such that the second temperature code TCc may increase as the operation temperature increases.

The calculation circuit 354 may generate a first digital temperature code TCD1 by calculating a difference between the first temperature code TCp and the second temperature code TCc. The calculation circuit 354 may generate the first digital temperature code TCD1 by subtracting the second temperature code TCc from the first temperature code TCp such that the first digital temperature code TCD1 may decrease as the operation temperature decreases.

The multiplexer 355, in response to a selection signal SS, may select one of the first digital temperature code TCD1 and the first temperature code TCp as the digital temperature code TCD.

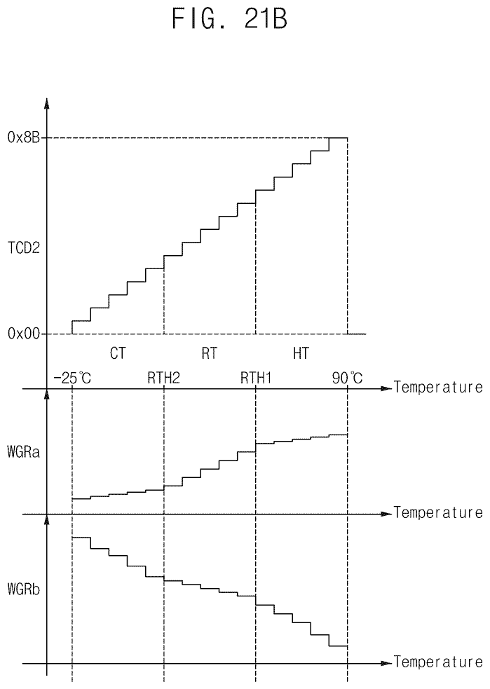

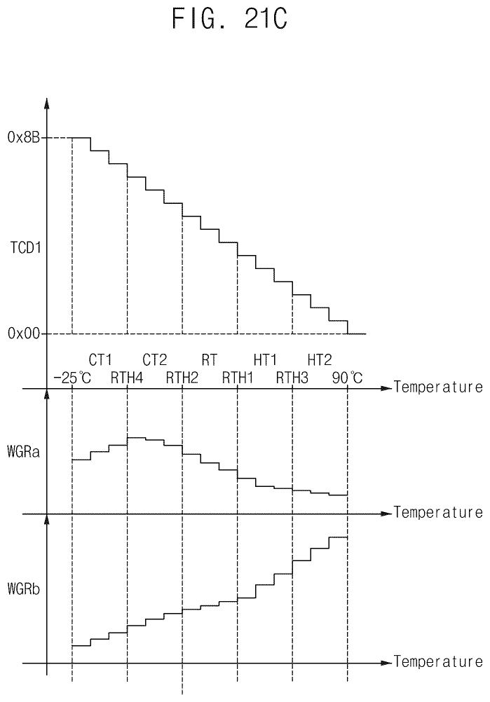

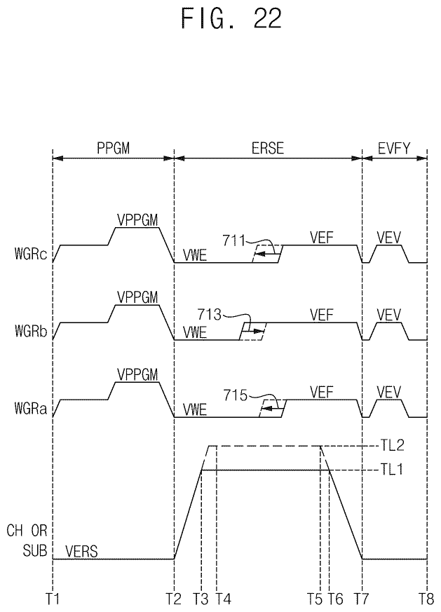

FIG. 21A illustrates a digital temperature code based on the operating temperature and compensation amount on a portion of the word-line groups based on the operating temperature according to example embodiments.

Referring to FIG. 21A, the plurality of temperature ranges may include a first temperature range HT equal to or greater than the first reference temperature RTH1, a second temperature range CT equal to or smaller than the second reference temperature RTH2 and a third temperature range RT between the first reference temperature RTH1 and the second reference temperature RTH2. In addition, the digital temperature sensor 350 of FIG. 20 may output the first digital temperature code TCD1 having values that decreases from 0x8B to 0x00 as the operating temperature increases.

The control circuit 450, based on the first digital temperature code TCD1, may control an erase operation on word-line of the word-lines group WGRa such that compensation amount of an erase execution time interval is increased as the operating temperature becomes higher and may control an erase operation on word-lines of the word-line group WGRb such that compensation amount of an erase execution time interval is decreased as the operating temperature becomes higher.

FIG. 21B illustrates a digital temperature code based on the operating temperature and compensation amount on a portion of the word-line groups based on the operating temperature according to example embodiments.

Referring to FIG. 21B, the plurality of temperature ranges may include a first temperature range HT equal to or greater than the first reference temperature RTH1, a second temperature range CT equal to or smaller than the second reference temperature RTH2 and a third temperature range RT between the first reference temperature RTH1 and the second reference temperature RTH2. In addition, the digital temperature sensor 350 of FIG. 20 may output a second digital temperature code TCD2 having values that increases from 0x8B to 0x00 as the operating temperature increases.

The control circuit 450, based on the second digital temperature code TCD2, may control an erase operation on word-line of the word-lines group WGRa such that compensation amount of an erase execution time interval is increased as the operating temperature becomes higher and may may control an erase operation on word-lines of the word-line group WGRb such that compensation amount of an erase execution time interval is decreased as the operating temperature becomes higher.

FIG. 21C illustrates a digital temperature code based on the operating temperature and compensation amount on a portion of the word-line groups based on the operating temperature according to example embodiments.

Referring to FIG. 21C, the first temperature range HT in FIG. 21A may be divided into first sub ranges HT1 and HT2 based on a third reference temperature RTH3 and the second temperature range CT in FIG. 21A may be divided into second sub ranges CTI and CT2 based on a fourth reference temperature RTH4. In addition, the digital temperature sensor 350 of FIG. 20 may output the first digital temperature code TCD1 having values that decreases from 0x8B to 0x00 as the operating temperature increases. The third reference temperature RTH3 may be greater than the first reference temperature RTH1 and the fourth reference temperature RTH4 may be smaller than the second reference temperature RTH2.

The control circuit 450, based on the first digital temperature code TCD1, may control an erase operation on word-line of the word-lines group WGRa such that compensation amount of an erase execution time interval is increased in the second sub region CT1 as the operating temperature becomes higher and may control an erase operation on word-lines of the word-line group WGRa such that compensation amount of an erase execution time interval is decreased in the second sub range CT2, the third temperature range RT, and the first sub ranges HT1 and HT2 as the operating temperature becomes higher. The control circuit 450, based on the first digital temperature code TCD1, may control an erase operation on word-lines of the word-line group WGRb such that compensation amount of an erase execution time interval is increased as the operating temperature becomes higher.

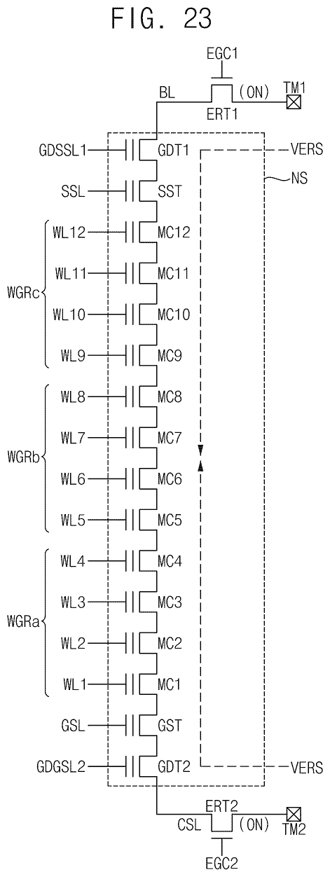

FIG. 22 is a timing diagram illustrating a method of operating a nonvolatile memory device according to example embodiments.

FIG. 22 illustrates a pre-program period PPGM, an erase execution (time) period ERSE and an erase verification period EVFY of one of a plurality of erase loops. Time points T1, T2, T7, and T8 represent boundaries of the periods.

Referring to FIG. 22, during the pre-program period PPGM between the time points T1 and T2, a pre-program voltage VPPGM may be applied to the word-lines of the target memory block. Therefore, memory cells in the target memory block are pre-programmed.

During the erase execution (time) period ERSE between the time points T2 and T5, an erase voltage VERS may be applied to a channel CH of the target memory block or to the substrate SUB. The erase voltage VERS may start to ramp at the time point T2, arrive at a first target level TL1 at a time point T3 and arrive at a second target level TL2 at a time point T4. The erase voltage VERS may start to decrease form the second target level TL2 at a time point T5, start to decrease form the first target level TL1 at a time point T6, and arrive at a level of a ground voltage at a time point T7.

When the sensed temperature is in the first temperature range, the word-line erase voltage VWE may be applied to word-lines of each of the word-line groups WGRa, WGRb, and WGRc until an individual (a corresponding) first time point between the time points T3 and T6 and the word-line inhibit voltage VEF may be applied to the word-lines of each of the word-line groups WGRa, WGRb, and WGRc from the individual (the corresponding) first time point. Therefore, erase operation may be performed on memory cells coupled ((electrically) connected) to the word-lines of each of the word-line groups WGRa, WGRb and WGRc from the time point T3 to the individual (the corresponding) first time point in each of the word-line groups WGRa, WGRb, and WGRc and the memory cells coupled ((electrically) connected) to the word-lines of each of the word-line groups WGRa, WGRb, and WGRc are erased.

When the sensed temperature is in the second temperature range, the word-line erase voltage VWE may be applied to the word-lines of each of the word-line groups WGRa, WGRb and WGRc until an individual (a corresponding) second time point between the time points T4 and T5 and the word-line inhibit voltage VEF may be applied to the word-lines of each of the word-line groups WGRa, WGRb and WGRc from the individual (the corresponding) second time point. Therefore, erase operation may be performed on memory cells coupled ((electrically) connected) to the word-lines of each of the word-line groups WGRa, WGRb and WGRc from the time point T4 to the individual (the corresponding) second time point in each of the word-line groups WGRa, WGRb and WGRc and the memory cells coupled ((electrically) connected) to the word-lines of each of the word-line groups WGRa, WGRb and WGRc are erased.

The second time point may be earlier than the first time point in each of the word-line groups WGRa and WGRc as reference numerals 711 and 715 indicate. The second time point may be later than the first time point in word-line group WGRb as a reference numeral 713 indicates. The adjusted amount of erase execution time interval for compensating for degradation of erase distribution width generated by a change of the operating temperature may be different in each of the word-line groups WGRa, WGRb and WGRc.

During the erase verification period EVFY between the time points T7 and T8, an erase verification voltage VEV may be applied to the memory cells in the target memory block for verifying erased states of the memory cells coupled ((electrically) connected) to the word-lines of the target memory block.

FIG. 23 illustrates an example of a cell string on which an erase operation is performed according to example embodiments.

In FIG. 23, a cell string NS may include a GIDL ground selection transistor GDT2, a ground selection transistor GST, a plurality of memory cells MC1 to MC12, a string selection transistor SST, and a GIDL string selection transistor GDT1 (electrically) connected in series between the common source line CSL and the bit-line BL. The GIDL ground selection transistor GDT2 may be coupled ((electrically) connected) to a GIDL ground selection line GDGSL2 and the GIDL string selection transistor GDT1 may be coupled ((electrically) connected) to a GIDL string selection line GDSSL1. The erase transistor ERT1 may be (electrically) connected between the bit-line BL and a first terminal TM1 and may have a gate receiving the erase control signal EGC1. The erase transistor ERT2 may be (electrically) connected between the common source line CSL and a second terminal TM2 and may have a gate receiving the erase control signal EGC2.

In addition, word-lines WL1 to WL12 of the cell string NS may be divided into the plurality of word-line groups WGRa, WGRb, and WGRc.

When the erase operation is performed on the cell string NS in FIG. 23, the erase voltage VERS may be applied to a channel CH of the cell string NS through the erase transistors ERT1 and ERT 2 by applying the erase control signals EGC1 and EGC2 to the erase transistors ERT1 and ERT2, respectively, to turn-on the erase transistors ERT1 and ERT2.

As described with reference to FIG. 22, when erase operation is performed on the cell string NS, the control circuit 450 in FIG. 9 may control the voltage generator 500 and the address decoder 600 to adjust erase execution time interval on each of the word-line groups WGRa, WGRb and WGRc, individually (respectively), based on the operating temperature of the nonvolatile memory device 100. The control circuit 450 may adjust erase execution time interval on each of the word-line groups WGRa, WGRb and WGRc, individually (respectively), by applying the erase voltage VERS to the channel CH of the cell string NS, by applying a word-line erase voltage (e.g., the word-line erase voltage VWE) to the word-lines of the each of the word-line groups WGRa, WGRb and WGRc and by adjusting a time point of applying the erase inhibit voltage (e.g., the erase inhibit voltage VEF) to the word-lines of the each of the word-line groups WGRa, WGRb and WGRc.

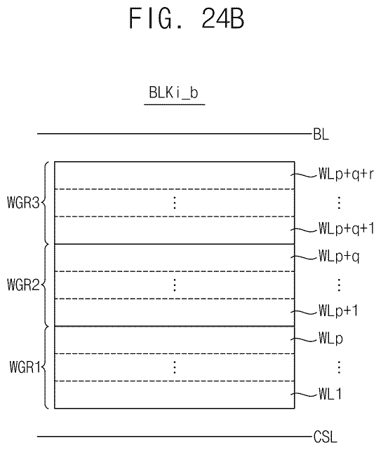

FIGS. 24A and 24B are diagrams of examples of word-line groups included in a memory block on which an erase operation is performed, according to example embodiments.

Referring to FIG. 24A, a memory block BLKi_a may include a plurality of word-lines WL1 to WLM and the plurality of word-lines WL1 to WLM may be divided into first through k-th word-line groups WGR1, WGR2, . . . , WGRk (k is a natural number greater than 2). That is, the memory block BLKi_a may include three or more word-line groups WGR1, WGR2, . . . , WGRk. The word-line groups WGR1, WGR2, . . . , WGRk may be respectively coupled ((electrically) connected) to the same number of word-lines, and the number of memory cells included in the word-line groups WGR1, WGR2, . . . , WGRk may be identical to each other. However, this is merely an example, and various embodiments may be made. For example, the number of word-lines (electrically) connected to the word-line groups WGR1, WGR2, . . . , WGRk may be different from each other, and the number of memory cells included in the word-line groups WGR1, WGR2, . . . , WGRk may be different from each other. A position of each of the word-line groups WGR1, WGR2, . . . , WGRk may be defined with respect to the bit-line BL or the common source line CSL. For example, first to j-th word-line groups WGR1 to WGRj (where, j is a natural number less than k−1) may be defined to be adjacent to the common source line CSL, and (j+1)-th to k-th word-line groups WGR (j+1) to WGRk may be defined to be adjacent to the bit-line BL.

When the control circuit 450 in FIG. 9 performs an erase operation on one or more word-line groups to be erased from among the word-line groups WGR1, WGR2, . . . , WGRk, the control circuit 450 may adjust an erase execution time interval of the word-line groups WGR1, WGR2, . . . , WGRk, individually (respectively). A number of the word-line groups WGR1, WGR2,, WGRk and a number of word-lines in each of the word-line groups WGR1, WGR2, . . . , WGRk may be varied based on a result of erase verification operation in each of a plurality of ease loops.

Referring to FIG. 24B, a memory block BLKi_b may include the first word-line group WGRa, the second word-line group WGRb and the third word-line group WGRc (electrically) connected to the different numbers of word-lines. For example, the first word-line group WGRa may be (electrically) connected to p word-lines WL1 to WLp, the second word-line group WGRb may be (electrically) connected to q word-lines WL(p+1) to WL(p+q) and the third word-line group WGRc may be (electrically) connected to r word-lines WL(p+q+1) to WL(p+q+r).

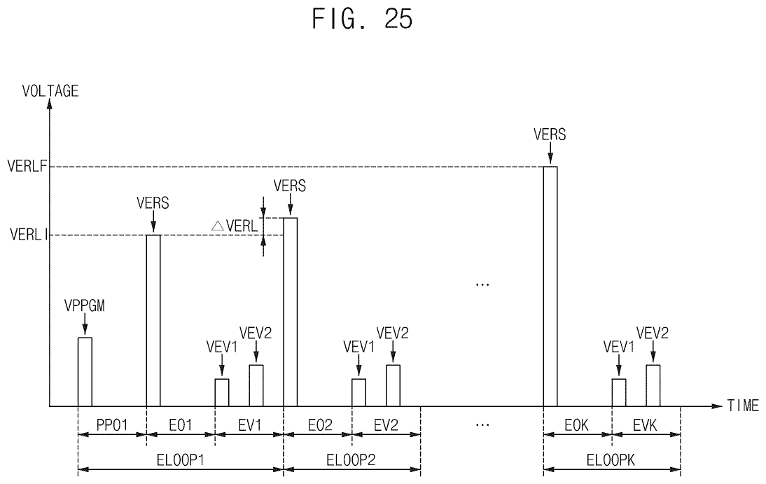

FIG. 25 illustrates an example of a plurality of erase loops performed on at a target memory block according to example embodiments.

Referring to FIG. 25, a plurality of erase loops ELOOP1, ELOOP2, . . . , ELOOPK may be sequentially performed, where K is a natural number greater than or equal to two. For each erase loop, one of erase operations EO1, EO2, . . . , EOK using the erase voltage VERS and a respective one of erase verification operations EV1, EV2, . . . , EVK using the erase verification voltage VEV may be sequentially performed. For the erase loop ELOOP1, a pre-program operation PPO1 using a pre-program voltage VPPGM may be performed prior to the erase operation EO1.

The pre-program operation PPO1 may be performed on memory cells coupled ((electrically) connected) to word-lines of the target memory block, and a respective one of the erase verification operations EV1, EV2, . . . , EVK may be performed on the memory cells ((electrically) connected) coupled to the word-lines of the target memory block by using the erase verification voltage VEV.

A level of the erase voltage VERS in a current erase loop may be higher than that of the erase voltage VERS in a previous erase loop, and the erase verification voltage VEV may have a constant level (e.g., a first verification level VEVL1).

For example, in the first erase loop ELOOP1, the erase voltage VERS may have an initial erase level VERLI. In the second erase loop ELOOP2, the erase voltage VERS may have a level that is increased by a step level ΔVERL from the initial erase level VERLI. In the K-th erase loop ELOOPK which is the last erase loop, the erase voltage VERS may have a final erase level VERLF.

Although FIG. 25 illustrates that only the level of the erase voltage VERS increases as the erase loop is repeated, example embodiments are not limited thereto, and the level of the erase verification voltage VEV may also increase. In some example embodiments, the level of the erase voltage VERS may decrease and/or the level of the erase verification voltage VEV may decrease as the erase loop is repeated. In addition, although FIG. 25 illustrates that the level of the erase voltage VERS increases by a fixed level (e.g., the step level ΔVERL), example embodiments are not limited thereto, and the amount of change in the erase voltage VERS may be changed for each erase loop.

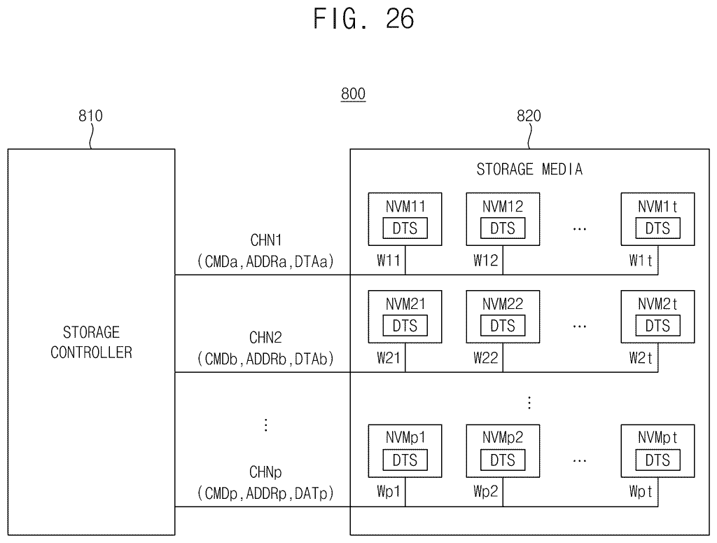

FIG. 26 is a block diagram illustrating a storage device according to example embodiments.

Referring to FIG. 26, a storage device 800 may include a storage controller 810 and a storage media 820. The storage device 800 may support a plurality of channels CHN1, CHN2, . . . , CHNp (hereinafter CHNI to CHNp), and the storage media 820 may be (electrically) connected to the storage controller 810 through the plurality of channels CHN1 to CHNp. Herein, p may be a natural number greater than two.

The storage media 820 may include a plurality of nonvolatile memory devices NVM11, NVM12, . . . , NVMIt, NVM21, NVM22, . . . , NVM2t, NVMp1, NVMp2, . . . , NVMpt. Herein, t may be a natural number greater than two. Each of the nonvolatile memory devices NVM11 to NVMpt may be (electrically) connected to one of the plurality of media channels CHN1 to CHNp through a way corresponding thereto. For instance, the nonvolatile memory devices NVM11 to NVM1t may be (electrically) connected to the first medial channel CHN1 through ways W11, W12, . . . , W1t, the nonvolatile memory devices NVM21 to NVM2t may be (electrically) connected to the second media channel CHN2 through ways W21, W22, . . . , W2t, and the nonvolatile memory devices NVMp1 to NVMpt may be (electrically) connected to the p-th media channel CHNp through ways Wp1, Wp2, . . . , Wpt. In some example embodiments, each of the nonvolatile memory devices NVM11 to NVMpt may be implemented as an arbitrary memory unit that may operate according to an individual (a respective) command from the storage controller 810. For example, each of the nonvolatile memory devices NVM11 to NVMpt may be implemented as a chip or a die, but example embodiments are not limited thereto.

Each of the nonvolatile memory devices NVM11 to NVMpt may include a digital temperature sensor DTS (e.g., the digital temperature sensor 350). The digital temperature sensor DTS may sense an operating temperature of a corresponding nonvolatile memory device and may provide a control circuit in the corresponding nonvolatile memory device with a digital temperature code (e.g., the digital temperature code TCD) corresponding to the sensed temperature. The control circuit may adjust erase execution time interval of a plurality of word-line groups, individually (respectively), when the control circuit performs an erase operation on a target memory block, based on the operating temperature of each of the nonvolatile memory devices NVM11 to NVMpt.

The storage controller 810 may transmit and receive signals to and from the storage media 820 through the plurality of media channels CHN1 to CHNp. For example, the storage controller 810 may correspond to the memory controller 50 in FIG. 8. For example, the storage controller 810 may transmit commands CMDa, CMDb, . . . , CMDp, addresses ADDRa, ADDRb, . . . , ADDRp and data DTAa, DTAb, . . . , DTAp to the storage media 820 through the media channels CHN1 to CHNp or may receive the DTAa to DTAp from the storage media 820.

The storage controller 810 may select one of the nonvolatile memories NVM11 to NVMpt, which is (electrically) connected to each of the media channels CHN1 to CHNp, by using a corresponding one of the media channels CHN1 to CHNp, and may transmit and receive signals to and from the selected nonvolatile memory device.

The storage controller 810 may transmit and receive signals to and from the storage media 820 in parallel through different media channels.

The storage controller 810 may communicate with an external host according to UFS standards.

A nonvolatile memory device or a storage device according to example embodiments may be packaged using various package types or package configurations.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims.

What is claimed is:

1. A method of operating a nonvolatile memory device that includes a plurality of memory blocks, each of the plurality of memory blocks including a plurality of cell strings where each of the plurality of cell strings includes a string selection transistor, a plurality of memory cells, and a ground selection transistor which are connected in series and arranged in a vertical direction between each of a plurality of bit-lines and a common source line on and/or in a substrate, the method comprising:
receiving an erase command and a block address designating a target memory block among the plurality of memory blocks;
sensing an operating temperature of the nonvolatile memory device; and
adjusting an erase execution time interval of each of word-lines of the target memory block, respectively, based on the sensed operating temperature,
wherein the vertical direction is perpendicular to an upper surface of the substrate.

2. The method of claim 1, wherein erase distribution width of ones of the plurality of memory cells connected to the word-lines of the target memory block, generated by a change of the operating temperature is configured to be reduced by adjusting the erase execution time interval of each of the word-lines of the target memory block, respectively.

3. The method of claim 1, wherein adjusting the erase execution time interval of each of the word-lines of the target memory block, respectively, includes:
dividing the word-lines of the target memory block into a plurality of word-line groups based on a distance in the vertical direction from the common source line; and
adjusting erase execution time interval of each of the word-line groups, respectively, based on the sensed operating temperature.

4. The method of claim 3, wherein adjusting the erase execution time interval of each of the word-line groups, respectively, includes:
setting a first erase bias condition corresponding to a first temperature range in response to the sensed operating temperature being in the first temperature range greater than a first reference temperature; and
performing a first erase operation on the target memory block based on the first erase bias condition.

5. The method of claim 4, wherein performing the first erase operation includes:
applying an erase voltage having a first target voltage to the substrate on and/or in which the plurality of cell strings are provided or a channel of the target memory block during an erase execution time period that comprises the erase execution time interval;
applying a word-line erase voltage to the word-lines of the target memory block while the erase voltage having the first target voltage is applied; and
applying an erase inhibit voltage to word-lines in each of the word-line groups at a corresponding first time point in the erase execution time period.

6. The method of claim 4, adjusting the erase execution time interval of each of the word-line groups, respectively, further includes:
setting a second erase bias condition corresponding to a second temperature range in response to the sensed operating temperature being in the second temperature range less than a second reference temperature; and
performing a second erase operation on the target memory block based on the second erase bias condition.

7. The method of claim 6, wherein performing the second erase operation includes:
applying an erase voltage having a second target voltage to the substrate in which the plurality of cell strings are provided or a channel of the target memory block during an erase execution time period that comprises the erase execution time interval, the second target voltage being greater than a first target voltage;
applying a word-line erase voltage to the word-lines of the target memory block while the erase voltage having the second target voltage is applied; and
applying an erase inhibit voltage to word-lines in each of the word-line groups at a corresponding second time point in the erase execution time period,
wherein the first target voltage is associated with the first erase operation, and
wherein the corresponding second time point is different from a corresponding first time point associated with the first erase operation.

8. The method of claim 7,
wherein the corresponding second time point is earlier than the corresponding first time point in a first word-line group among the plurality of word-line groups, and
wherein the corresponding second time point is later than the corresponding first time point in a second word-line group different from the first word-line group among the plurality of word-line groups.

9. The method of claim 1, further comprising:
determining a temperature range of the sensed operating temperature among a plurality of temperature ranges.

10. The method of claim 9, wherein the plurality of temperature ranges include a first temperature range greater than a first reference temperature, a second temperature range less than a second reference temperature and a third temperature range between the first temperature range and the second temperature range,
wherein the first reference temperature is greater than the second reference temperature,
wherein the first temperature range is divided into a plurality of first sub ranges, and
wherein the second temperature range is divided into a plurality of second sub ranges.

11. The method of claim 10, wherein adjusting the erase execution time interval of each of the word-lines of the target memory block, respectively, further includes:
dividing the word-lines of the target memory block into a plurality of word-line groups based on a distance in the vertical direction from the common source line; and
adjusting time point of applying an erase inhibit voltage to word-lines in each of the word-line groups, in each of the plurality of first sub ranges and the plurality of second sub ranges.

12. The method of claim 1, wherein the sensed operating temperature is configured to be provided as a digital temperature code, and a value of the digital temperature code is proportional or inversely proportional to the operating temperature of the nonvolatile memory device,
wherein word-lines of the target memory block are divided into a plurality of word-line groups based on a distance in the vertical direction from the common source line,
wherein adjusting the erase execution time interval of each of the word-lines of the target memory block, respectively, includes adjusting time point of applying an erase inhibit voltage to word-lines in each of the word-line groups, based on the digital temperature code, and
wherein a number of word-lines in each of at least two of the plurality of word-line groups are different from each other.

13. A nonvolatile memory device comprising:
a memory cell array including a plurality of memory blocks, each of the plurality of memory blocks including a plurality of cell strings where each of the plurality of cell strings includes a string selection transistor, a plurality of memory cells, and a ground selection transistor which are connected in series and arranged in a vertical direction between each of a plurality of bit-lines and a common source line on and/or in a substrate;
a digital temperature sensor configured to sense an operating temperature of the nonvolatile memory device; and
a control circuit configured to control an erase operation on a target memory block among the plurality of memory blocks by;
receiving an erase command and a block address designating the target memory block; and
adjusting an erase execution time interval of each of word-lines of the target memory block, respectively, based on the sensed operating temperature, and
wherein the vertical direction is perpendicular to an upper surface of the substrate.

14. The nonvolatile memory device of claim 13, further comprising:
a voltage generator configured to generate word-line voltages including an erase voltage, a word-line erase voltage, and an erase inhibit voltage based on control signals; and
an address decoder configured to provide the word-line voltages to the target memory block based on a row address.

15. The nonvolatile memory device of claim 14, wherein the control circuit is configured to:
divide the word-lines of the target memory block into a plurality of word-line groups based on a distance in the vertical direction from the common source line;
set a first erase bias condition corresponding to a first temperature range in response to the sensed operating temperature being in the first temperature range greater than a first reference temperature; and
perform a first erase operation on the target memory block based on the first erase bias condition.

16. The nonvolatile memory device of claim 15, wherein the control circuit is further configured to control the voltage generator and the address decoder to perform the first erase operation by:
applying the erase voltage having a first target voltage to the substrate on and/or in which the plurality of cell strings are provided or a channel of the target memory block during an erase execution time period that comprises the erase execution time interval;
applying the word-line erase voltage to the word-lines of the target memory block while the erase voltage having the first target voltage is applied; and
applying the erase inhibit voltage to word-lines in each of the word-line groups at a corresponding first time point in the erase execution time period.

17. The nonvolatile memory device of claim 15, wherein the control circuit is further configured to:
set a second erase bias condition corresponding to a second temperature range in response to the sensed operating temperature being in the second temperature range less than a second reference temperature; and
performing a second erase operation on the target memory block based on the second erase bias condition.

18. The nonvolatile memory device of claim 17, wherein the control circuit is further configured to control the voltage generator and the address decoder to perform the second erase operation by:
applying the erase voltage having a second target voltage to the substrate on and/or in which the plurality of cell strings are provided or a channel of the target memory block during an erase execution time period that comprises the erase execution time interval, the second target voltage being greater than a first target voltage;
applying the word-line erase voltage to the word-lines of the target memory block while the erase voltage having the second target voltage is applied; and
applying the erase inhibit voltage to word-lines in each of the word-line groups at a corresponding second time point in the erase execution time period,
wherein the first target voltage is associated with the first erase operation, and
wherein the second time point is different from a first time point associated with the first erase operation.

19. The nonvolatile memory device of claim 13, wherein the digital temperature sensor is configured to provide the sensed operating temperature as a digital temperature code,
wherein a value of the digital temperature code is proportional or inversely proportional to the operating temperature of the nonvolatile memory device,
wherein the word-lines of the target memory block are divided into a plurality of word-line groups based on a distance in the vertical direction from the common source line, and
wherein the control circuit is configured to adjust the erase execution time interval of each of the word-lines of the target memory block, respectively, by adjusting time point of applying an erase inhibit voltage to word-lines in each of the word-line groups, based on the digital temperature code.

20. A nonvolatile memory device comprising:
a memory cell array including a plurality of memory blocks, each of the plurality of memory blocks including a plurality of cell strings where each of the plurality of cell strings includes a string selection transistor, a plurality of memory cells, and a ground selection transistor which are connected in series and arranged in a vertical direction between each of a plurality of bit-lines and a common source line on and/or in a substrate;
a digital temperature sensor configured to sense an operating temperature of the nonvolatile memory device; and
a control circuit configured to control an erase operation on a target memory block among the plurality of memory blocks by;
receiving an erase command and a block address designating the target memory block; and
adjusting an erase execution time interval of each of word-lines of the target memory block, respectively, based on the sensed operating temperature,
wherein the control circuit is configured to:
divide the word-lines of the target memory block into a plurality of word-line groups based on a distance in the vertical direction from the common source line;
apply an erase voltage to a channel of the target memory block during an erase execution time period that comprises the erase execution time interval;
apply a word-line erase voltage to the word-lines of the target memory block while the erase voltage having a first target voltage is applied; and
adjust time point of applying an erase inhibit voltage to word-lines in each of the word-line groups, based on a digital temperature code corresponding to the sensed operating temperature, and
wherein the vertical direction is perpendicular to an upper surface of the substrate.
